(19) United States
(12) Patent Application Publication
(10) Pub. No.: US 2008/0150096 A1
(43) Pub. Date: Jun. 26, 2008

(54) MULTI-CHIP MODULE, MANUFACTURING METHOD THEREOF, MOUNTING STRUCTURE OF MULTI-CHIP MODULE, AND MANUFACTURING METHOD OF MOUNTING STRUCTURE

(75) Inventor: Toshiya ISHIO, Nabari-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 11/960,042

(22) Filed: Dec. 19, 2007

(30) Foreign Application Priority Data
Dec. 21, 2006 (JP) 2006-345015

(51) Int. Cl. H01L 23/552

(52) U.S. Cl. 257/659; 257/E23.114

(57) ABSTRACT

With respect to the central plane which horizontally cuts a multi-chip module, constituent materials of the same type are disposed in a plane symmetrical manner. Each of an upper structure and a lower structure, which sandwich the central plane which horizontally cuts the multi-chip module, includes a base and electronic components, as the aforesaid constituent materials.

This Nonprovisional application claims priority under 35 U.S.C. § 119(a) on Patent Application No. 345015/2006 filed in Japan on Dec. 21, 2006, the entire contents of which are hereby incorporated by reference.

### FIELD OF THE INVENTION

The present invention relates to a multi-chip module constituted by plural components (such as an electronic component, a substrate, and wiring), a mounting structure of the multi-chip module, and a manufacturing method thereof.

### BACKGROUND OF THE INVENTION

There have been proposed multi-chip modules in each of which plural semiconductor chips are mounted at the central part of a silicon substrate for the purpose of reduction in planar size, and column-shaped electrodes are provided around the outer periphery of the upper surface of the silicon substrate (e.g. Patent Document 1 (Japanese Laid-Open Patent Application No. 2001-94033; published on Apr. 6, 2001).

For example, as shown in FIG. 10 the conventional multi-chip module 120 includes a silicon substrate 103 on which semiconductor chips 101 are provided in plane. To mount each semiconductor chip 101 thereon, the silicon substrate 103 is arranged such that lands 110 made of aluminum are formed at the central part whereas lands 111 made of aluminum are formed at the peripheral part. At the central part of each of the lands 110 and 111, an opening penetrating an insulating film is formed. Each semiconductor chip 101 is connected to the lands 110 through the intermediary of solder bumps 115, in a face-down manner. The lands 111 are connected to column-shaped electrodes 112 made of copper, respectively, through the intermediary of a titan thin film and a copper thin film. The semiconductor chips 101 are sealed in a sealing resin 105 so as to be disposed inside the multi-chip module 120. The tip of each column-shaped electrode 112 juts out from the sealing resin 105, and this jutting portion functions as a terminal (solder bump 116 for external connection.

Between the silicon substrate 103 and the sealing resin 105, an organic film 106 is provided. The area where the silicon substrate 103 and the organic film 106 are formed is termed substrate area 102, whereas the area where the semiconductor chips 101, the column-shaped electrodes 112, and the sealing resin 105 are formed is termed sealing area 104.

This conventional multi-chip module is disadvantageous in that the multi-chip module warps, because of the reason below.

In the aforesaid multi-chip module 120, the semiconductor chips 101 and the sealing resin 105 are formed on one side of the silicon substrate 103. Since the members in the substrate area 102 and the members in the sealing area 104 are made of different materials, the physical properties such as coefficient of linear expansion, elastic modulus, and melting temperature or glass-transition temperature are different between the substrate area 102 and the sealing area 104. For this reason, in the thermal process for hardening the sealing resin 105 in the steps of manufacturing the multi-chip module 120, the multi-chip module 120 warps while the temperature decreases from the thermal process temperature to the room temperatures.

The warpage is particularly significant when plural semiconductor chips 101 are mounted in the flat. Because of this warpage, connection between the multi-chip module 120 and another substrate cannot be sufficiently established.

The conventional multi-chip module 120 is mounted on another substrate, through the intermediary of the solder bumps 116. The solder bumps 116 are provided at the peripheral part of the multi-chip module 120. If the multi-chip module 120 has a circular shape viewed from the silicon substrate 103 side of the multi-chip module 120, the center of the circle is the most jutted when the multi-chip module 120 warps. If the multi-chip module 120 warps substantially evenly around the perpendicular line passing through the center, the multi-chip module 120 can be attached to another substrate in some way, on condition that the size of the multi-chip module 120 is small. However, since the multi-chip module typically has a rectangular shape, the height of each solder bump at the center of each edge of the rectangle is different from the height of each solder bump at each apex of the rectangle, even if the multi-chip module evenly warps. Furthermore, if solder bumps are also provided at the central part of the multi-chip module, differences among the heights of solder bumps due to the warpage of the multi-chip module are more severe. Therefore, a multi-chip module having a rectangular shape cannot be attached to a substrate even if the warpage of the module is slight. In addition to this, as the size of a multi-chip module increases, attaching the multi-chip module to a substrate becomes more difficult.

As discussed above, a multi-chip module includes plural semiconductor chips therein. Each of these semiconductor chip independently influences on the multi-chip module so that the multi-chip module warps at different parts. Since these warps are intricately combined in the multi-chip module, the multi-chip module rarely warps evenly, i.e. typically warps unevenly. As a result, it is very difficult to attach the multi-chip module to a substrate.

In addition to the above, considering all electronic components other than semiconductor chips, which are mounted on the multi-chip module, it is extremely difficult to make the sizes of these electronic components be even. In particular, the uneven warpage of the multi-chip module is further significant when electronic components having different heights are provided therein.

Furthermore, the conventional multi-chip module does not take account of the relationship between the coefficient of linear expansion of the multi-chip module and the coefficient of linear expansion of the substrate to which the multi-chip module is attached. For this reason, once the multi-chip module is mounted (connected) to a substrate, the assembly of the multi-chip module and the substrate warps altogether. Therefore, after the connection of these members, the members in the multi-chip module (e.g. internal connection section, external connection section, and wires) may be broken during use.

### SUMMARY OF THE INVENTION

The present invention was done to solve the problem above, and the objective of the present invention is to provide a multi-chip module which can reduce its warpage, a manufacturing method thereof, a mounting structure of the multi-chip module, and a manufacturing method of the structure.

To achieve the objective above, a multi-chip module, including constituent materials therein, is characterized in that the constituent materials of the same type being disposed to be plane symmetrical with respect to a central plane which horizontally cuts the multi-chip module.

According to the arrangement above, assuming that a part of the multi-chip module above the central plane which horizontally cuts the multi-chip module is an upper structure whereas the remaining part of the multi-chip module below the central plane is a lower structure, the arrangements in the upper structure and the arrangements in the lower structure are substantially plane symmetrical with respect to the central plane which horizontally cuts the multi-chip module. The upper and lower structures therefore warp in opposite directions. In other words, the upper and lower structures cancel out the warping forces of each other. Consequently the multi-chip module can reduce its warpage.

Furthermore, because the warpage of the multi-chip module is reduced, the multi-chip module can be surely connected to another substrate. Moreover, even if a temperature change occurs in the use environment after the mounting, connection failure between the substrate and the multi-chip module is restrained because the warpage of the multi-chip module is small.

To achieve the objective above, a multi-chip module, including constituent materials therein, is characterized in that each of an upper structure and a lower structure sandwiching a central plane which horizontally cuts the multi-chip module including, as the constituent materials, a base and electronic components.

According to the arrangement above, principal parts of the upper structure above the central plane which horizontally cuts the multi-chip module and principal parts of the lower structure below the central plane are substantially identical. Therefore in terms of the elongation and contraction in one direction due to temperature changes, the upper and lower structures are identical with each other. In other words, since the difference in the degree of elongation and contraction between the upper and lower structures is small, an in-plane stress is restrained. As a result, the warpage of the multi-chip module is reduced.

Furthermore, because the warpage of the multi-chip module is reduced, the multi-chip module can be surely connected to another substrate. Moreover, even if a temperature change occurs in the use environment after the mounting, connection failure between the substrate and the multi-chip module is restrained because the warpage of the multi-chip module is small.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a vertical cross section of a multi-chip module of an embodiment of the present invention.

FIG. 2(a) to FIG. 2(e) are vertical cross sections of the multi-chip module, corresponding to respective manufacturing steps.

FIG. 3 is a vertical cross section of a multi-chip module of another embodiment of the present invention.

FIG. 4 is a vertical cross section of a multi-chip module of a further embodiment of the present invention.

FIG. 5 is a vertical cross section of a multi-chip module of yet another embodiment of the present invention.

FIG. 6(a) to FIG. 6(g) are vertical cross sections of the multi-chip module, corresponding to respective manufacturing steps.

FIG. 7 is a vertical cross section of a multi-chip module of the present invention, in which conductive materials and insulating materials are provided in order to arrange the bodies of electronic components in a substantially plane symmetric manner.

FIG. 8 is a vertical cross section of a multi-chip module, for the sake of explaining the idea of the present invention.

FIG. 9(a) and FIG. 9(b) are schematic representations of a multi-chip module of the present invention, in the longitudinal direction and in the maximal length direction, respectively.

FIG. 10 is a vertical cross section of a conventional multi-chip module.

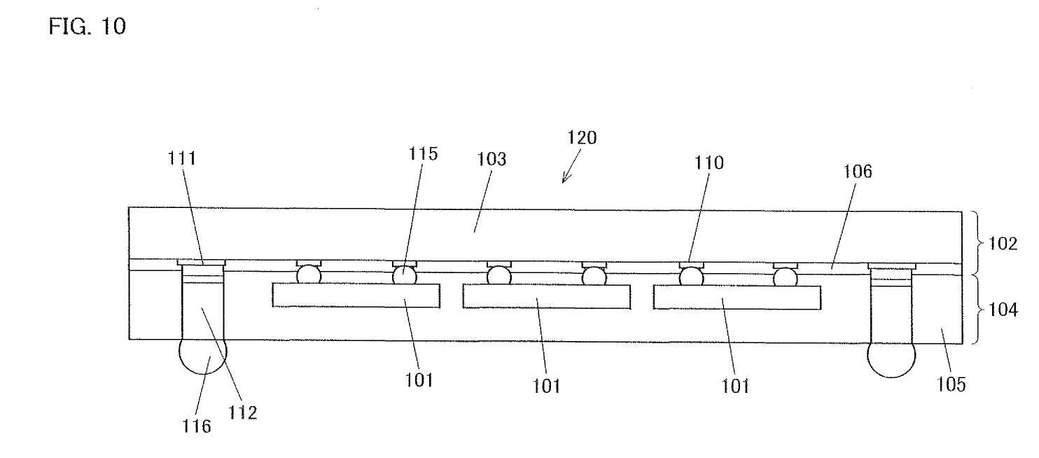

### DESCRIPTION OF THE EMBODIMENTS

The basic idea of the present invention will be explained first.

The inventors of the present invention made a study on an arrangement of main constituent members in a multi-chip module, and completed the present invention thanks to the discovery of the prevention of warpage occurring in manufacturing steps or the like of the multi-chip module.

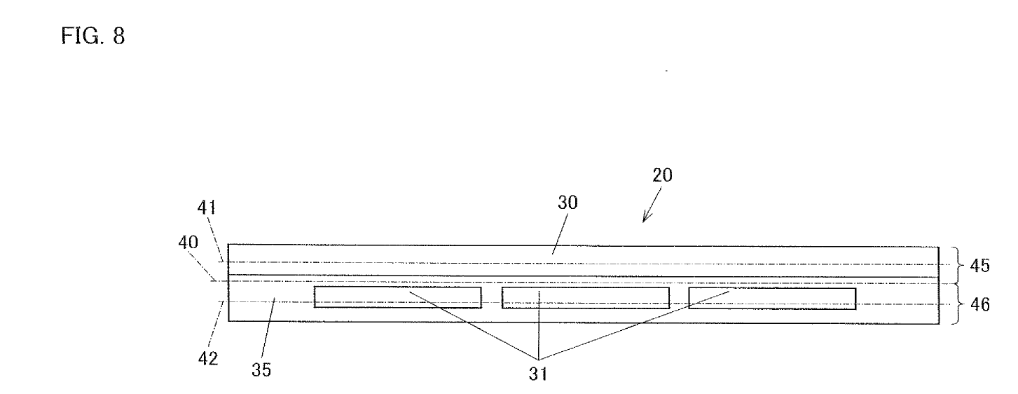

For example, as shown in FIG. 8, a multi-chip module 20 is arranged such that three electronic components 31 are mounted on a silicon substrate 30. In FIG. 8, the dotted line 40 indicates a central plane of the multi-chip module 20 in the horizontal cross sectional direction. That is to say, the multi-chip module 20 is divided, by the central plane, into an upper structure 45 and a lower structure 46. In FIG. 8, the dotted line 41 indicates a central plane of the upper structure 45 in the horizontal cross sectional direction, whereas the dotted line 42 indicates a central plane of the lower structure 46 in the horizontal cross sectional direction.

Around the electronic components 31, sealing resin 35 is formed. In other words, the lower structure 46 is filled with the sealing resin 35 except the areas where the electronic component 31 are provided. Assuming that the electronic components 31 are silicon chips, the coefficients of linear expansion of the silicon substrate 30, the electronic components 31, and the sealing resin 35 have the relationship indicated by the following expression (I):

Coefficient of linear expansion of electronic component 31=Coefficient of linear expansion of silicon substrate 30<Coefficient of linear expansion of sealing resin 35 (I)

The relationship between the coefficients of linear expansion of the upper structure 45 and the lower structure 46 is therefore as indicated by the following expression (II).

Coefficient of linear expansion of upper structure 45<Coefficient of linear expansion of lower structure 46 (II)

In consequence, as the temperature increases or decreases, the lower structure 46 extends or contracts in a greater degree than the upper structure 45. As the lower structure 46 extends, the multi-chip module 20 warps so as to be convexed downward (toward the lower structure 46 side). On the other hand, as the lower structure 46 contracts, the multi-chip module 20 warps so as to be convexed upward (toward the upper structure 45 side).

Details of the upper structure 45 and the lower structure 46 will be given.

In the upper structure 45, the volume of the silicon substrate 30 is larger in the part above the dotted line 41 than the part below the dotted line 41. Because of this, as the temperature increases or decreases, the part below the dotted line 41 (i.e. the part contacting the lower structure 46) extends or contracts in a greater degree than the part above the dotted line 41. For this reason, the upper structure 45 warps so as to be convexed downward as the temperature increases, whereas the upper structure 45 warps so as to be convexed upward as the temperature decreases.

In the meanwhile, in the lower structure 46, the body volume of the electronic components 31 is larger in the part above the dotted line 42 (i.e. the part contacting the upper structure 45) than the part below the dotted line 42. As a result, as the temperature increases or decreases, the part below the dotted line 42 extends or contracts in a greater degree than the part above the dotted line 42. Therefore, the lower structure 46 warps so as to be convexed downward when the temperature increases, whereas the lower structure 46 warps so as to be convexed upward when the temperature decreases.

In other words, the upper structure 45 and the lower structure 46 warp in the same direction, as the temperature increases or decreases. As a result, the multi-chip module 20 greatly warps as the temperature increases or decreases.

In consideration of the above, the inventors of the present invention came up with the idea that the warpage of the multi-chip module 20 can be reduced by arranging the upper structure 45 and the lower structure 46 to warp in opposite directions and cancel out the warps as the temperature increases or decreases.

The warpage of the multi-chip module 20 can be reduced by arranging the members in the upper structure 45 and the members in the lower structure 46 to be plane symmetrical with respect to the central plane of the multi-chip module 20 in the horizontal cross sectional direction, i.e. with respect to the dotted line 40. Conceiving of this arrangement, the inventors completed the present invention.

In some cases, the structure of the multi-chip module 20 does not allow the members in the upper structure 45 to be precisely plane symmetrical with the members in the lower structure 46. In such cases, the degrees of contraction and extension of the upper structure 45 in plane are arranged to be substantially identical with those of the lower structure 46, by arranging the parameters (e.g. total volume, total surface area, and quantity of the electronic components 31) of the members in the upper structure 45 to be substantially identical with those of the members in the lower structure 46. As a result, it is possible to restrain an in-plane stress between the upper structure 45 and the lower structure 46, and hence the warpage of the multi-chip module 20 is reduced. To put it differently, the inventors completed the present invention by coming up with the idea that the warpage of the multi-chip module 20 is reduced by arranging the parameters (e.g. coefficient of linear expansion, elastic modulus, glass-transition temperature, quantity, surface area, volume, and arrangement) of the members in the upper structure 45 to be substantially identical with those of the members in the lower structure 46.

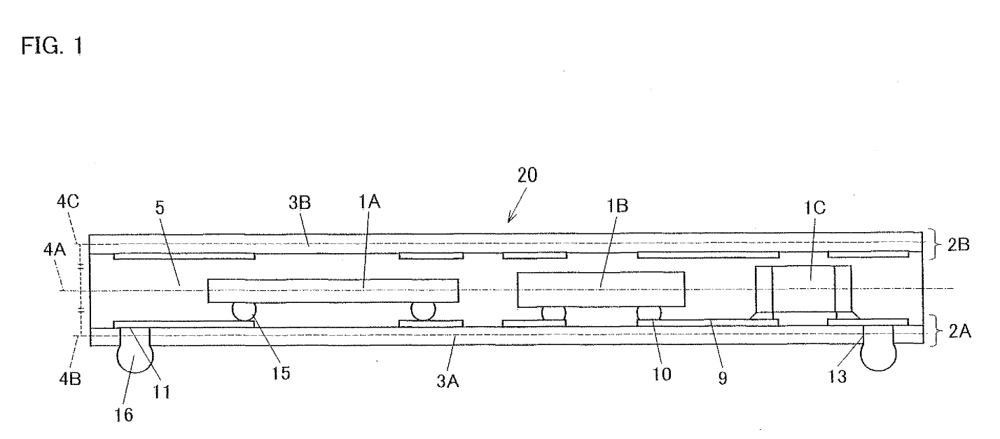

The following will explain an embodiment of the present invention with reference to FIGS. 1-7 and FIG. 9. The present invention, however, is not limited to this embodiment.

In this specification, “horizontal cross sectional direction” indicates the direction in which constituent materials of a multi-chip module are deposited.

Also, in this specification, “constituent materials of the same type” indicates constituent materials having the same function. Non-limiting examples of them include wires, electronic components, and bases.

Also, in this specification, “plane symmetrical” indicates a state in which at least one components are symmetrically provided with respect to the central plane or the like. In other words, when at least one arrangements are plane symmetrical, two areas are arranged in a symmetrical manner, and one constituent material or a part of one constituent material is provided in one area (e.g. space) whereas at least one of the other constituent materials or the remaining part of the constituent material is provided in the other area.

### Embodiment 1

A multi-chip module of the present embodiment will be explained with reference to FIG. 1.

FIG. 1 is a cross section of the multi-chip module of the present embodiment.

The multi-chip module 20 shown in FIG. 1 includes an electronic component 1A, an electronic component 1B, and an electronic components 1C (i.e. bodies of electronic components) which are disposed in plane. The electronic component 1A and the electronic component 1B are active components including ICs and having different body sizes (i.e. different in planar size and thickness of each body). The electronic component 1C is a passive component having a different body size from the 1C components 1A and 1B. In the present embodiment, the electronic component 1A, electronic component 1B, and electronic component 1C are IC chips and a chip capacitor. The present invention, however, is not limited to this arrangement.

The body sizes of the electronic component 1A, electronic component 1B, and electronic component 1C can be optionally determined, on condition that these components can be mounted on the multi-chip module. For example, preferably the multi-chip module 20 is 0.7 mm thick, the electronic component 1A has the body size of 4.0×40.0×0.16 mm, the electronic component 1B has the body size of 3.5×3.5×0.2 mm, and the electronic component 1C has the body size of 0.6×0.3×0.3 mm. These specific values are examples and hence the present invention is not limited to them.

In the multi-chip module of the present embodiment, the electronic component 1A, electronic component 1B, and electronic component 1C may have bodies entirely coated by resin or the like. In this case, the resin is regarded as a part of the body of each electronic component. Publicly-known resins can be optionally used as the aforesaid resin.

In the multi-chip module of the present embodiment, the electronic components are provided inside the multi-chip module, as components of the module. For this reason, the electronic component are not necessarily coated with sealing resin, and hence the example below assumes that the substrate made of silicon or the like functions as the body of an electronic component (bare chip or wafer-level CSP). In this specification, unless otherwise noted, “electronic component” indicates “body” of an electronic component. This “body” of an electronic component is a main body excluding an external connection terminal, of an electronic component such as IC, transistor, diode, sensor, piezoelectric element, capacitor, resistor, coil, filter, varistor, and chip bead. “Wafer-level CSP” indicates CSP (chip scale Package) by which package is directly fabricated on a wafer, and the final form of the package has a chip-size body. In wafer-level CSP, only the element surface of the IC chip is typically sealed by resin, and hence the sides of the IC chip and the bottom surface opposite to the element surface of the IC chip are not sealed. The external connection terminal is connected to a wire connected to an electrode pad section of the IC chip. The electronic component 1A, electronic component 1B, and electronic component 1C are electrically connected, via terminals 15 which are conductive materials, to a land section 10 which is a part of wiring 9 which is made of a conductive material and formed on the base 3A.

The wirings 9 (lands 10 and 11) may be optionally chosen on condition that it is made of a conductive material. For example, the wirings 9 (lands 10 and 11) are preferably made of copper which excels in the electric conduction properties. The thickness of the wirings 9 (lands 10 and 11) may also be optionally chosen, on condition that it can be mounted on the multi-chip module. For example, the wirings 9 (lands 10 and 11) are preferably 0.02 mm thick. With this thickness, the electric conductivity of the wiring is high.

The terminals 15 may be optionally chosen on condition that the electronic component 1A, electronic component 1B, and electronic component 1C are connected to the lands 10. For example, the terminals 15 are preferably made of a material for bumps, such as solder, copper, and gold. In the multi-chip module of the present embodiment, solder is chosen as the material because of its suitability for the connection to the lands 10.

In the multi-chip module of the present embodiment, the electronic component 1A, electronic component 1B, and electronic component 1C which are connected to the base 3A are covered with the base 3A and base 3B and coated by the sealing resin 5.

The sealing resin 5 may be optionally chosen, and hence publicly-known resin can be suitably adopted. An example of the resin is thermosetting epoxy resin. The sealing resin 5 preferably includes filler such as silica. It is preferable that the coefficient of linear expansion of the sealing resin 5 be brought close to the coefficient of linear expansion of the base 3A by adjusting the ratio of filler in the sealing resin 5. According to this arrangement, since the distribution of the coefficients of linear expansion is further uniformalized in the multi-chip module, the warpage of the multi-chip module is further reduced.

Furthermore, in the multi-chip module of the present embodiment, the bases 3A and 3B are provided so as to sandwich the electronic component 1A, electronic component 1B, and electronic component 1C. The electronic component 1A, electronic component 1B, and electronic component 1C are provided so as to be substantially plane symmetrical with respect to the central plane 4A which horizontally cuts the multi-chip module 20, and the base 3A and base 3B are also provided so as to be substantially plane symmetrical. In other words, the bodies of the electronic component 1A, electronic component 1B, and electronic component 1C, which are the main constituent materials, are provided so as to overlap the central plane which horizontally cuts the multi-chip module 20. Since the bodies of the electronic component 1A, electronic component 1B, and electronic component 1C overlap the central plane horizontally cutting the multi-chip module 20, the warpage of the multi-chip module 20 is reduced.

In the multi-chip module of the present embodiment, as shown in FIG. 1, it is more preferable that the central plane which horizontally cuts the multi-chip module 20 overlap the central planes which horizontally cut the electronic component 1A, electronic component 1B, and electronic component 1C. This makes it possible to further reduce the warpage of the multi-chip module 20.

To further ensure the reduction of the warpage, in the multi-chip module of the present embodiment, the thickness of each of the bases 3A and 3B is preferably 0.15 mm (wiring is preferably 0.02 mm thick), provided that the total thickness of the multi-chip module 20 is 0.7 mm. In this case, the average height of the terminals 15 is preferably about 0.1 mm on the electronic component 1A, about 0.08 mm on the electronic component 1B, and about 0.03 mm on the electronic component 1C. In the case above, furthermore, the bodies of the electronic component 1A, electronic component 1B, and electronic component 1C are preferably 0.16 mm thick, 0.2 mm thick, and 0.3 mm thick, respectively. These arrangements further ensure the prevention of the warpage of the multi-chip module. Since these specific values are mere examples, the present invention is not limited to them.

In addition to the above, in the multi-chip module of the present embodiment, the base 3A and base 3B are equally distanced from the central plane which horizontally cuts the multi-chip module 20. In other words, the bases 3A and base 3B are arranged to be substantially plane symmetrical with respect to the central plane which horizontally cuts the multi-chip module 20. To put it differently, the bases 3A and 3B are disposed in such a way that virtual surfaces 4B and 4C, which are equally distanced from the central plane 4A of the multi-chip module 20 from above and below, overlap the bases 3A and 3B, respectively. This makes it possible to reduce the warpage of the multi-chip module 20.

In the multi-chip module of the present embodiment, the central planes horizontally cutting the respective bases 3A and 3B are preferably disposed so as to be equally distanced from the central plane horizontally cutting the multi-chip module 20. In other words, the bases 3A and 3B are preferably disposed in such a way that the central planes horizontally cutting the base 3A and base 3B overlap the virtual surface 4B and virtual surface 4C, respectively. This arrangement further ensures the reduction of the warpage. In this case, although the thickness of each of the bases 3A and 3B may be optionally determined, it is preferable that the bases 3A and 3B are identical in thickness.

In addition to the above, the base 3A and base 3B have substantially identical coefficients of linear expansion in the XY direction. This further ensures the reduction of the warpage of the multi-chip module. In this specification, “XY direction(s)” indicates all directions or one direction on a plane of the multi-chip module. In other words, all directions or one direction on a surface on which the base 3A or 3B is provided is termed XY direction(s).

For example, in case where the multi-chip module 20 is long and narrow, the elongation and contraction of the base 3A and base 3B in the widthwise direction of the multi-chip module 20 does not greatly influences on the warpage of the multi-chip module 20. For this reason, the coefficients of linear expansion of the base 3A and base 3B may be substantially identical with one another only in the longitudinal direction or the maximal length direction of the multi-chip module. In case where the multi-chip module 20 has an irregular shape, only the coefficients of linear expansion at a part where the width of the base is the longest may be substantially identical with one another. In case where the base 3A and base 3B have different shapes, the coefficients of linear expansion may be made to be substantially identical with one another only at an area where the bases 3A and base 3B overlap one another and the width is the longest.

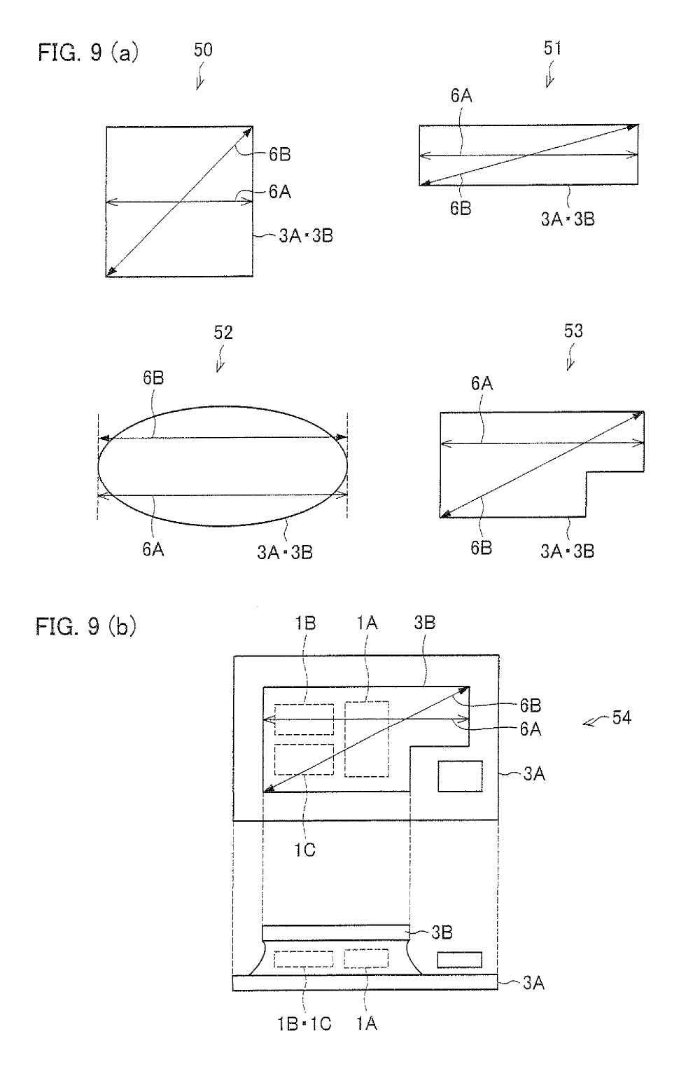

As an example, FIG. 9(a) is a schematic drawing of multi-chip modules each of which is formed by combining bases 3A and 3B having the same shape. In a multi-chip module 50, the base 3A and base 3B are square-shaped. In a multi-chip module 51, the base 3A and base 3B are rectangular-shaped. In a multi-chip module 52, the base 3A and base 3B are elliptically-shaped. In a multi-chip module 53, the base 3A and base 3B are irregularly-shaped. In FIG. 9(a), the arrow 6A indicates the longitudinal direction of a multi-chip module, and the arrow 6B indicates the maximal length direction of a multi-chip module. In other words, the longitudinal directions of the respective bases are in parallel to the longitudinal direction of the multi-chip module, whereas the maximal length directions of the respective bases are in parallel to the maximal length direction of the multi-chip module.

FIG. 9(b) is a schematic drawing of a multi-chip module 54 which is formed by combining the base 3A and base 3B having different shapes with one another. In FIG. 9(b), the base 3A has a rectangular shape whereas the base 3B has an irregular shape. The base 3B is disposed so as to entirely overlap the base 3A. In FIG. 9(b), the arrow 6A indicates the longitudinal direction of the multi-chip module and the arrow 6B indicates the maximal length direction of the multi-chip module. In other words, the longitudinal direction of the smaller base is in parallel to the longitudinal direction of the multi-chip module, and the maximal length direction of the smaller base is in parallel to the maximal length direction of the multi-chip module.

In the multi-chip module of the present embodiment, the elastic moduli and glass-transition temperatures of the base 3A and base 3B are preferably substantially identical. As to the elastic moduli, being similar to the case of the coefficients of linear expansion, only the longitudinal direction or the maximum length direction of the bases is taken into consideration, depending on the planar shape of the multi-chip module. With this, the warpage of the multi-chip module is reduced. In the multi-chip module of the present embodiment, the base 3A and base 3B are preferably made of the same material, in order to attain the same coefficients of linear expansion, elastic moduli, and glass-transition temperatures. Assuming that the base 3A and base 3B are made of the same material, the balance between the degree of adhesion between the base 3A and the sealing resin 15 and the degree of adhesion between the base 3B and the sealing resin 15 are fine. When there are plural boundary surfaces, the frequency of boundary separation is typically determined by the boundary surface at which the adhesion is the weakest, no matter how the degree of adhesion at another boundary surface is high. The arrangement above therefore prevents boundary separation.

The material of which the bases are made is not particularly limited. Preferred examples of the material include epoxy resin, polyimide resin, ceramic, and silicon material.

The base 3A and base 3B may be made of a composite material produced by mixing two or more materials. In this case, two or more materials are preferably mixed in consideration of not only the types of materials but also the component ratio, the sizes of the ingredients, and the distribution of the ingredients. For example, the bases may be produced in such a manner that resin (e.g. epoxy resin, cyanate resin) is impregnated into glass fiber, organic fiber, or the like. In this case, the coefficient of linear expansion, elastic modulus, water absorption and the like of the base are varied in accordance with the component ratio of the materials, the length of a fiber, the direction of fibers, the state of distribution (woven or non-woven), and the like. Therefore, to form the base 3A and base 3B, not only the type of the material of which the bases are made but also the constituent ratio, the average length of fibers, the average diameter of fibers, and the state of distribution (direction, woven or non-woven) are preferably identical between the bases. In addition, the base 3A and base 3B preferably include filler, along with the fiber. In regard to this, the constituent ratio of the filler and the average size of the filler are preferably the same between the bases.

In case where the base 3A and base 3B are printed wiring substrates produced by impregnating liquid epoxy resin into glass cloth which is woven glass fiber, the base 3A and base 3B are preferably produced in accordance with the following conditions, in consideration of the above. The difference in the constituent ratios of glass to resin between the base 3A and base 3B is preferably not more than 20 wt %, and the difference in the glass-transition temperatures between the base 3A and base 3B is preferably not higher than 20° C. High glass-transition temperatures are preferred, and hence, for example, the glass-transition temperatures of 160-180° C. are preferable. The difference in the coefficients of linear expansion between the base 3A and base 3B is preferably not higher than 10 ppm/° C. in at least one of the XY directions. When the temperatures are not lower than the glass-transition temperatures, the difference is preferably not higher than 100 ppm/° C. in the XY directions. The difference in water absorption between the base 3A and base 3B is preferably not larger than 0.2 wt %.

In the multi-chip module of the present embodiment, the electronic components 1A, 1B, and 1C are mounted on (connected to) only the base 3A. The base 3B is not connected to the outside and hence the base 3B does not require wirings 9. However, to further restrain the warpage of the multi-chip module 20, the wirings 9 are preferably provided on the inner side of each of the base 3A and base 3B. The number of layers of the wirings 9 may be optionally determined. The wirings 9 have a single layer or plural layers being deposited.

It is possible to optionally determine the difference between the covering ratio of the wirings 9 provided on the base 3A (ratio of the surface area of the wirings 9 to the surface area of the base) and the covering ratio of the wirings 9 provided on the base 3B. The difference is preferably not more than 20%. Most preferably, these covering ratios are identical. This further ensures the reduction in the warpage of the multi-chip module.

In the multi-chip module of the present embodiment, since the bodies of the electronic component 1A, electronic component 1B, and electronic component 1C are different in thickness, the heights of the electronic components are adjusted by adjusting the heights of the terminals 15. Alternatively, the heights of the terminals 15 may be adjusted so that the bodies of the electronic component 1A, electronic component 1B are identical in thickness and the bodies of the electronic component 1A, electronic component 1B, and electronic component 1C are disposed on the central plane horizontally cutting the multi-chip module 20. (Adjusting the terminals 15 to have desired heights is also necessary for a symmetrical arrangement. This holds true for a case where a die bond material or the like is used.) Needless to say, it is often difficult to adjust the bodies of electronic components of different types to have the same thickness. To suitably adjust the positions of the bodies of the electronic components, the terminals 15 are preferably bumps made of a conductive material such as gold, copper, and solder, and further preferably the bumps are used in complex with ACF (Anisotropic Conductive Film) or ACP (Anisotropic Conductive Paste), both of which are conductive materials. ACE is a resin film including conductive particles, whereas ACP is liquid resin including conductive particles. ACF or ACP is pasted on or applied to the electronic component side or the base side, and thereafter thermo-compression is carried out so that electric connection is achieved via protrusions such as bumps. In case where the electronic components are mounted in a face-up manner, a die bond material may be a conductive adhesion which is a paste or sheet-shaped conductive material or an insulating adhesive which is an insulating material. Alternatively, the positions of the bodies of the electronic components are preferably adjusted in a suitable manner by adopting bases or the like which are made of an insulating material and changing the thickness or the number of layers of the bases. The positions of the bodies of the electronic components may be suitably adjusted by changing the thickness or the number of layers of the wirings 9 (lands 10) which are conductive materials.

The following will give further details of arrangements (conductive materials and insulating materials) in which the bodies of the electronic components are disposed in a substantially plane symmetrical manner with respect to the central plane horizontally cutting the multi-chip module of the present invention. It is noted that the arrangements explained below are mere examples and hence the present invention is not limited to these arrangements.

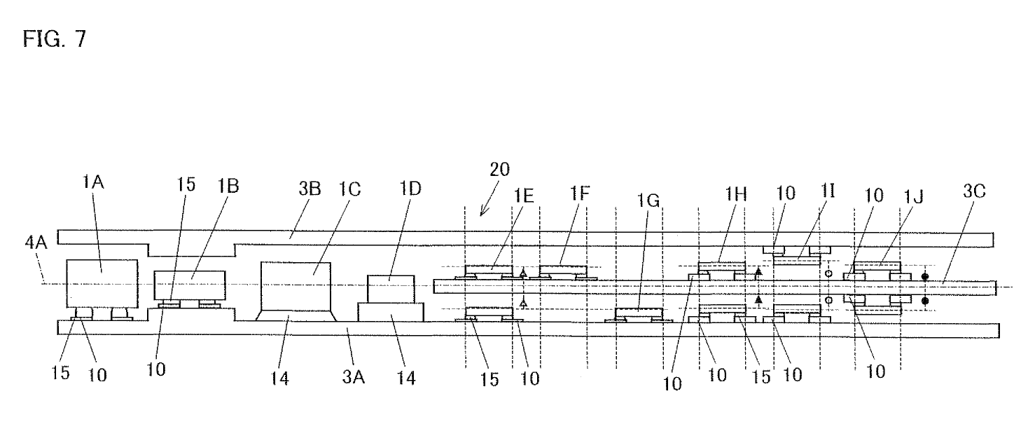

FIG. 7 shows various conductive and insulating materials for causing the electronic components to be disposed in a substantially plane symmetrical manner with respect to the central plane horizontally cutting the multi-chip module, and various disposition patterns of the electronic components disposed in a substantially plane symmetrical manner with respect to the central plane horizontally cutting the multi-chip module. In FIG. 7, components having the same symbol (e.g. triangle or circle) are distanced in the same distance from the central plane.

Comparing the electronic component 1A with the electronic component 1B, these electronic components are different in the thickness of the bodies. In this case, the bodies of the electronic component 1A and the electronic component 1B can be disposed so as to overlap the central plane of the multi-chip module 20, by increasing the thickness of the base 3A below the electronic component 1B and reducing the height of the terminals 15 which are conductive materials, as compared to those of the electronic component 1A. Most preferably, the central planes of the bodies of the electronic component 1A and the electronic component 1B overlap the central plane 4A of the multi-chip module 20. In addition, preferably the bases 3A and 3B having the same number of layers (e.g. one layer for each body) sandwich the bodies of the electronic component 1A and electronic component 1B. In the electronic component 1A and electronic component 1B, not only the disposition of the base 3A and 3B but also the thickness of the bases 3A and 3B are plane symmetrical with respect to the central plane. This arrangement makes it possible to restrain the warpage of the multi-chip module.

Comparing the electronic component 1C with the electronic component 1D, these electronic components are different in the thickness of the bodies. The electronic component 1C is disposed so that its body overlaps the central plane in the cross sectional direction of the multi-chip module, by reducing the thickness of the die bond material 14 which is an insulating material or a conductive material, as compared to the die bond material 14 of the electronic component 1D. (Electric connection is achieved by wire bonding or the like (bonding wires and the like are not illustrated)). The electric connection may be achieved by means other than the bonding wires. Non-limiting examples thereof are connection by means of a finger lead, which is used for TCP (Tape Carrier Package) and the like, and connection by plating. Also in this case, most preferably the central planes of the bodies of the electronic component 1C and electronic component 1D in the cross sectional direction overlap the central plane in the cross sectional direction of the multi-chip module. The die bond material 14 is a paste material, sheet-shaped material, or the like. The die bond material 14 may be conductive or insulating depending on whether a conductive material is included in the resin material. The resin material is preferably epoxy resin or polyimide resin. The conductive material is preferably silver. The sheet-shaped material is suitable for obtaining a desired height when mounted, as compared to the paste material. In the case of the paste material, a desired height can be easily achieved by adjusting the diameter of filler.

As to the electronic components 1E to 1J, the base 3C is disposed so as to overlap the central plane horizontally cutting the multi-chip module 20. Most preferably, the central plane horizontally cutting the base 3C overlaps the central plane horizontally cutting the multi-chip module 20, in consideration of the reduction of the warpage.

The electronic components 1E are disposed above and below the central plane 4A of the multi-chip module 20, as different members. The central planes horizontally cutting the bodies of the electronic components 1E, respectively, are disposed so as to be differently distanced from the central plane 4A horizontally cutting the multi-chip module 20. In the meanwhile, because of the existence of the base 3C, the virtual surfaces which are equally distanced from the central plane of the multi-chip module 20 from above and below overlap the respective bodies of the electronic components 1E. That is to say, by the base 3C (in this case the thickness of the wirings 9 (lands 10) which are conductive materials and the terminals 15 are also taken into account), the bodies of the electronic components 1E are disposed in a substantially plane symmetrical manner with respect to the central plane of the multi-chip module. In other words, the upper electronic component 1E can be disposed in a substantially plane symmetrical manner by adjusting the number of bases below the mounting area as compared to the lower electronic component 1E and the electronic components 1A-1D. The upper and lower electronic components 1E are preferably disposed at different areas, when vertically viewing the multi-chip module 20. Because the electronic components 1E are disposed in overlapped areas as above, it is possible to reduce a local warpage of the multi-chip module 20. Most preferably, the bodies of the electronic components 1E have the same planar size when the multi-chip module 20 is vertically viewed. Also when the planer sizes are slightly different, a local warpage of the multi-chip module 20 can be restrained if the components are disposed so as to overlap one another.

For example, FIG. 7 illustrates a multi-chip module on which fourteen electronic components are mounted in total. In this case, locally the electronic component 1F and electronic component 1G are not plane symmetrical in the cross section at the areas where the electronic components are mounted. The multi-chip module 20 therefore locally deforms. However, since the number of the bodies of the electronic components above the central plane of the multi-chip module 20 is identical with the number of the bodies of the electronic components below the central plane, the warpage of the multi-chip module 20 is restrained on the whole.

The warpage of the multi-chip module is restrained if the body sizes (total area in the XY directions, total volume, or both of them) are substantially identical between the electronic components 1A to 1J in the upper structure and the electronic components 1A to 1J in the lower structure. In this regard, moreover, between the total area of the electronic components 1A to 1J in the upper structure and the total area of the electronic components 1A to 1J in the lower structure, the ratio of the larger total area to the smaller total area is preferably not higher than 120%, or between the total volume of the electronic components 1A to 1J in the upper structure and the total volume of the electronic components 1A to 1J in the lower structure, the ratio of the larger total volume to the smaller total volume is preferably not higher than 120%. Most preferably, both the ratio between the larger total area to the smaller total area and the ratio between the larger total volume and the smaller total volume are not higher than 120%.

Each of the electronic components 1H has the wiring 9 (land 10) which is a conductive material and thicker than that of the electronic component 1E. Because of this, the central planes horizontally cutting the bodies of the electronic components 1H are arranged to be substantially plane symmetrical. That is to say, the central planes horizontally cutting the bodies of the upper and lower electronic components 1H are identically distanced from the central plane 4A horizontally cutting the multi-chip module 20. As compared to the electronic component 1E, the electronic components 1H further facilitates the reduction in the warpage of the multi-chip module 20.

The electronic components 1I are mounted on the respective bases 3A and 3B which are disposed in a substantially plane symmetrical manner. The electronic components 1J are mounted on the respective surfaces of the base 3C. Therefore, in case where the upper and lower wirings 9 (lands 10) are identical in thickness and in the thickness of the terminals 15, the central planes of the bodies of the upper and lower electronic components 1I are identically distanced from the central plane 4A of the multi-chip module 20, on condition that the electronic components 1I are thin enough to be housed in the multi-chip module 20. In the electronic components 1I or electronic components 1J, the wirings 9 constituting the multi-chip module 20 are preferably disposed to be plane symmetrical with respect to the central plane horizontally cutting the multi-chip module 20. It is noted that the effect is slightly improved if the die bond materials, underfill materials, ACF, ACP, bumps and the like are disposed in a plane symmetrical manner.

The following will describe the mounting structure for mounting a multi-chip module of the present invention on a substrate. The mounting structure discussed below can be used for all multi-chip modules of the present invention.

For example, the coefficient of linear expansion in the XY directions of the substrate, on which the multi-chip module 20 shown in FIG. 1 is mounted, is preferably identical with the coefficients of linear expansion in the XY directions of the bases 3A and 3B constituting the multi-chip module.

As discussed above, in case where the multi-chip module 20 is long and narrow, the elongation and contraction of the base 3A and base 3B in the widthwise direction of the multi-chip module 20 does not greatly influences on the warpage of the multi-chip module 20. For this reason, the coefficients of linear expansion of the base 3A and base 3B may be substantially identical with one another only in the longitudinal direction or the maximal length direction of the multi-chip module. In case where the multi-chip module 20 has an irregular shape, only the coefficients of linear expansion at a part where the width of the base is the longest may be substantially identical with one another. In case where the base 3A and base 3B have different shapes, the coefficients of linear expansion may be made to be substantially identical with one another only at an area where the bases 3A and base 3B overlap one another and the width is the longest. In this case, the coefficient of linear expansion of the substrate in the XY directions is substantially identical with the coefficients of linear expansion of the bases 3A and 3B, only in the direction in which the coefficients of linear expansion of the bases 3A and 3B are substantially identical.

Furthermore, the substrate on which the multi-chip module 20 is mounted preferably has the same elastic modulus and glass-transition temperature as those of the bases 3A and 3B constituting the multi-chip module 20. Being similar to the coefficients of linear expansion, the elastic moduli are made to be substantially the same only in the longitudinal direction or the maximal length direction, depending on the planar shape of the multi-chip module.

The substrate on which the multi-chip module 20 is mounted is preferably made of a material of which the bases 3A and 3B constituting the multi-chip module 20 are made. A non-limiting example of the substrate on which the multi-chip module 20 is mounted is a printed wiring substrate produced by impregnating liquid epoxy resin into glass cloth which is woven glass fiber.

The arrangements above ensure the reduction of the warpage of the multi-chip 20 mounted on the substrate. More specifically, the substrate preferably has the following physical properties. The difference in the component ratio of glass in resin and glass fiber between (i) the bases 3A and 3B and (ii) the substrate on which the multi-chip module 20 is mounted is preferably not higher than 20 wt %. The difference in the glass-transition temperatures between (i) the bases 3A and 3B and (ii) the substrate is preferably not higher than 20° C. High glass-transition temperatures are preferred, and hence, for example, the glass-transition temperatures of 160-180° C. are preferable. The difference in the coefficients of linear expansion between (i) the bases 3A and 3B and (ii) the substrate is preferably not higher than 10 ppm/° C. in at least one of the XY directions. When the temperatures are not lower than the glass-transition temperatures, the difference is preferably not higher than 100 ppm/° C. in the XY directions. The difference in water absorption between the bases 3A and 3B and the substrate is preferably not larger than 0.2 wt %.

To restrain the warpage after the multi-chip module is mounted on the substrate, the coefficients of linear expansion of the multi-chip module and the substrate are preferably substantially identical in the XY directions. In case where the substrate is made of a composite material as above, the coefficient of linear expansion is preferably adjusted by changing the rates of the constituent materials of the substrate. In case where the bases of the multi-chip module are made of a composite material, the coefficient of linear expansion is preferably adjusted by changing the rates of the constituent materials of the bases. In case where the sealing resin includes filler or the like, it is preferable to adjust the rate of content of the filler or the like. In case where the bases, the substrate, or both of them is not made of a composite material, the material is preferably chosen so that the coefficients of linear expansion of the bases and the substrate are substantially the same.

The multi-chip module explained above may be arranged as below. This arrangement will be explained with reference to FIG. 1.

The bases 3A and 3B are disposed so as to overlap the respective virtual surfaces 4A and 4B which are equally distanced from above and below from the central plane 4A horizontally cutting the multi-chip module 20. Most preferably the central planes horizontally cutting the respective bases 3A and 3B are equally distanced from the central plane 4A horizontally cutting the multi-chip module 20.

In the meanwhile, the electronic component 1A, electronic component 1B, and electronic component 1C have bodies which are different in thickness. Thanks to the terminals 15 made of a conductive material, the bodies of the electronic components 1A, 1B, and 1C are disposed so as to overlap the central plane horizontally cutting the multi-chip module 20. In this regard, the central planes horizontally cutting the bodies of the electronic component 1A, electronic component 1B, and electronic component 1C preferably overlap the central plane 4A horizontally cutting the multi-chip module 20.

That is to say, each of the structures above and below the central plane 4A horizontally cutting the multi-chip module 20 includes the base 3A or 3B, the half of the body of the electronic component 1A, the half of the body of the electronic component 1B, and the half of the body of the electronic component 1C, and the number of the bodies in the upper structure is identical with the number of the bodies in the lower structure. Moreover, the total area of the bodies of the electronic components in the upper structure is identical with the total area of the bodies of the electronic components in the lower structure, in the XY directions. Also, the total volume of the bodies of the electronic components in the upper structure is identical with the total volume of the bodies of the electronic components in the lower structure. In addition, the bodies of the electronic components in the upper structure overlap the bodies of the electronic components in the lower structure, when viewed in the direction perpendicular to the multi-chip module. The structures above and below the central plane horizontally cutting the multi-chip module are arranged so as to have substantially the same coefficients of linear expansion in all of the XY directions. Depending on the planar shape of the multi-chip module, it is effective to arrange the coefficients of linear expansion to be substantially identical in only the longitudinal direction or the maximal length direction of the multi-chip module. It is further effective to arrange the coefficients of linear expansion to be substantially identical in all of the XY directions.

When the multi-chip module is mounted on the substrate, it is easy to arrange the coefficient of linear expansion of the bases of the multi-chip module and the coefficient of linear expansion of the substrate on which the multi-chip module is mounted to be identical in the XY directions, and this reduces the warpage. To further restrain the warpage of the multi-chip module mounted on the substrate, the coefficients of linear expansion of the upper structure, the lower structure and the substrate are arranged to be identical in all of the XY directions. Depending on the planar shape of the multi-chip module, the coefficients of linear expansion of the upper structure, the lower structure and the substrate may be arranged to be substantially identical only in the longitudinal direction or the maximal length direction of the multi-chip module. In case where the substrate is made of a composite material, the rates of the constituent materials of the substrate are preferably adjusted in a suitable manner. In case where the bases of the multi-chip module are made of a composite material, the rates of the constituent materials of the bases are preferably adjusted in a suitable manner. In case of sealing resin including filler or the like, it is preferable to adjust the rate of content of the filler or the like. In case where the bases, the substrate, or both of them is not made of a composite material, the material is preferably chosen so that the coefficients of linear expansion of the upper structure, the lower structure and the substrate are substantially the same.

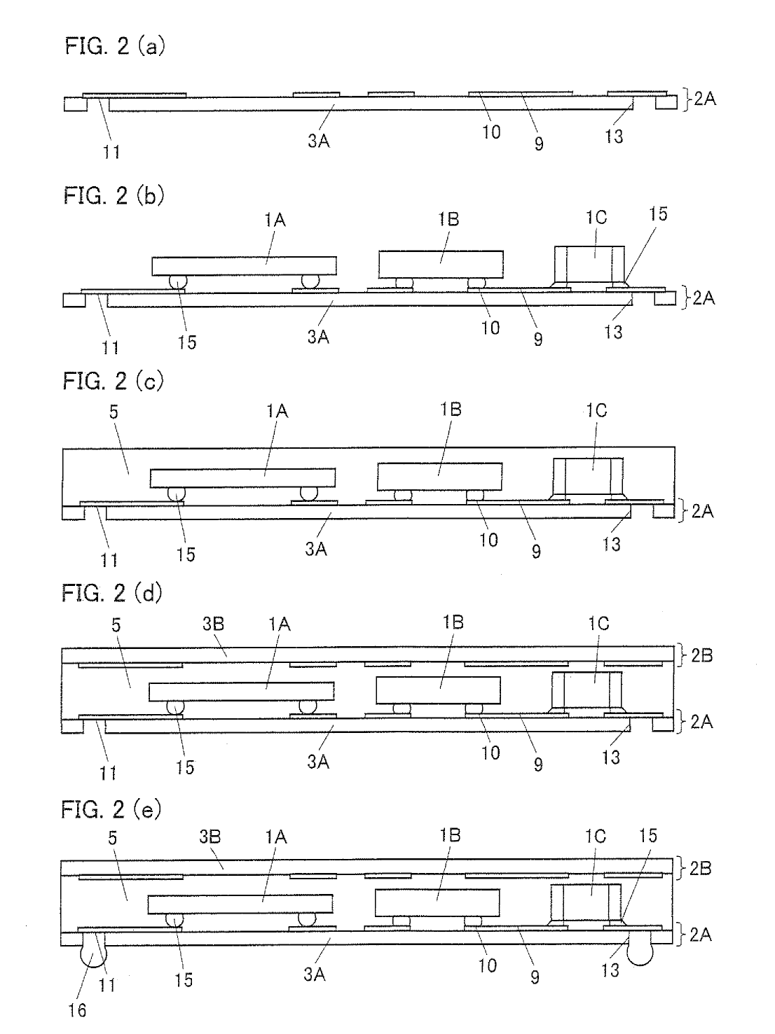

The following will explain a manufacturing method of the multi-chip module of the present embodiment, with reference to FIGS. 2(a)-2(e).

First, as shown in FIG. 2(a), a material produced by impregnating liquid epoxy resin into glass cloth which is woven glass fiber is prepared as a base 3A which is an insulating material, and wirings 9 (lands 10 and 11) are formed on the base 3A. If a shielding layer is required, preferably a shielding layer is provided on the surface of the base 3A, which is opposite to the surface where the wirings 9 are formed, Alternatively, a shielding layer is provided on the surface where the wirings 9 are formed, avoiding the patterns of the wirings 9. In some cases, a shielding layer may be provided inside the base 3A. In any embodiments, the multi-chip module of the present invention is preferably arranged such that bases with shielding layers are disposed in a plane symmetrical manner with respect to the central plane horizontally cutting the multi-chip module. This arrangement further ensures the reduction of the warpage of the multi-chip module.

Openings 13 are formed by using, for example, a drill. Preferably, in consideration of easiness of manufacture, plural bases 3A are formed as connected strips or tapes of multi-chip modules, and separated into each base in the subsequent step (which is performed after the step shown in FIG. 2(e)) As to the base 3B, preferably plural bases 3A are formed as connected strips or tapes of multi-chip modules, too. For the sake of convenience, the figure illustrates a cross section of a single multi-chip module.

Subsequently, as shown in FIG. 2(b), the electronic component 1A, electronic component 1B, and electronic component 1C are flatly disposed on the lands 10 of the base 3A. In doing so, because the bodies of these electronic component are different in thickness, terminals 15 which are different in height are formed on the electronic components side or the lands 10 side. In case where the terminals 15 are formed on the electronic components side, the step of forming the terminals 15 is simplified by forming them on wafers in which the electronic components are made. In this case, solder bumps which are different in height are formed on parts of the wafers in which the electronic component 1A and the electronic component 1B are formed, respectively, so that the electronic component 1A and the electronic component 1B have desired heights after being connected to the lands 10.

More specifically, for example, on the lands 10 of the base 3A, paste solder is provided by, for example, printing. Subsequently, the electronic component 1A, electronic component 1B, and electronic component 1C are mounted by using a mounter, and electric connections are established by thermal treatment. To differentiate the heights of the solder bumps of the electronic component 1A and electronic component 1B, solder balls having different sizes are mounted on the terminal sections of the electronic components 1A and 1B in the wafers, by a ball mounting method, and then thermal treatment is performed. Alternatively, solder is printed with the thickness and opening size of the print mask being varied, and thermal treatment is performed. As to the electronic component 1C, the terminals 15 thereof is arranged to be thinner than those of the other electronic components, because paste solder is supplied only on the base 3A side so that the terminals 15 are formed.

Thereafter, after mounting the electronic component 1A, electronic component 1B, and electronic component 1C on the base 3A, thermal treatment is carried out so that the electronic component 1A, electronic component 1B, and electronic component 1C are connected to the base 3A in such a manner that the bodies of the electronic component 1A, electronic component 1B, and electronic component 1C overlap the central plane horizontally cutting the multi-chip module having desired thickness. In doing so, preferably the heights of the terminals 15 are adjusted so that the central planes horizontally cutting the respective bodies of the electronic component 1A, electronic component 1B, and electronic component 1C overlap the central plane horizontally cutting the multi-chip module. According to the method of manufacturing the multi-chip module of the present embodiment, the bodies of the electronic component 1A, electronic component 1B, and electronic component 1C are disposed on the central plane horizontally cutting the multi-chip module, by forming the terminals 15 made of a solder material. The material of the terminals 15 can be optionally chosen, and hence the material may be another conductive material such as copper and gold. To form bumps with desired heights by electroplating, the process time or current density may be suitably varied.

The bumps may be formed by thin metallic wires. In this case, the bumps are preferably formed in manner of the first bonding of wire bonding. The heights of the bumps can be suitably adjusted by varying, for example, the wire diameter and the pressure for the bonding.

The electronic components 1A and 1B may be mounted in a face-up manner. In this case, the die bond material is preferably arranged to have desired thickness. Also, electric connections between the base 3A and the wirings 9 of the electronic component 1A and electronic component 1B are preferably achieved by wire bonding.

Thereafter, as shown in FIG. 2(c), after each space between the neighboring terminals 15 of the electronic component 1A, electronic component 1B, and electronic component 1C mounted on the base 3A is filled with liquid resin (e.g. underfill material; not illustrated), the electronic component 1A, electronic component 1B, and electronic component 1C are externally sealed by the sealing resin 5. In doing so, it is preferable to perform the resin sealing after the liquid resin filling the space between the terminals 15 is hardened. The resin sealing may be suitably performed in various ways, such as a well-known method. Examples of the resin sealing methods include transfer molding, potting, drawing, and spin coating.

The sealing resin 5 may be completely hardened. Preferably, the below-mentioned base 3B is attached while the sealing resin 5 is liquid or half-hard. This makes it easy to attach the base 3B. While the base 3B is attached after the resin sealing in the explanation above, resin may be injected between the bases 3A and 3B, after these bases 3A and 3B are arranged to face one another. In this case, a spacer (not illustrated) is preferably provided between the base 3A and base 3B. The spacer is may be provided inside or outside the area of the strip-shaped or tape-shaped bases 3A and 3B for forming the multi-chip module. In case of transfer molding, a spacer may not be used, and sealing resin having desired thickness can be formed by tentatively attaching the bases 3A and 3B to the upper and lower dies by vacuum attaching or the like. Alternatively, the sealing resin may be formed in such a manner that the bases 3A and 3B are tentatively attached to the upper and lower jigs by vacuum attaching or the like and liquid resin is injected.

Then the base 3B is attached as shown in FIG. 2(d). This base 3B preferably has substantially the same coefficient of linear expansion as the base 3A. In case where the planer shape of the multi-chip module is long and narrow or irregular, the base 3A and base 3B may have substantially the same coefficients of linear expansion only in the longitudinal direction or the maximal length direction of the multi-chip module. As a matter of course, the warpage of the multi-chip module is further reduced if the coefficients of linear expansion are substantially the same in all of the XY directions. Furthermore, more preferably the base 3B has the same elastic modulus and glass-transition temperature as the base 3A. The elastic moduli are preferably substantially identical in all of the XY directions of the multi-chip module. Alternatively, depending on the planar shape of the multi-chip module, the elastic moduli may be substantially identical only in the longitudinal direction or the maximal length direction of the multi-chip module, as in the case of the coefficients of linear expansion. Therefore, the base 3B is most preferably made of the same type of material as the base 3A. This further reduces the warpage of the multi-chip module.

The base 3A and base 3B preferably have substantially the same coefficients of linear expansion, elastic moduli, and glass-transition temperatures as the substrate on which the multi-chip module is mounted. In case where the planar shape of the multi-chip module is long and narrow or irregular, the coefficient of linear expansion of the substrate on which the multi-chip module is mounted may be substantially the same as those of the bases 3A and 3B, only in the longitudinal direction or the maximal length direction of the multi-chip module. As a matter of course, the warpage of the multi-chip module is further reduced if the coefficients of linear expansion of the bases constituting the multi-chip module are substantially the same as that of the substrate on which the multi-chip module is mounted, in all of the XY directions. Therefore the bases 3A and 3B are more preferably made of the same type of material as the substrate on which the multi-chip module is mounted. As discussed above, the coefficients of linear expansion of the upper and lower structures are most preferably identical with the coefficient of linear expansion of the substrate on which the structures are mounted. This makes it possible to reduce the warpage occurring after the multi-chip module is mounted on the substrate.

The base 3B is preferably mounted on the half-hard or liquid sealing resin 5 and adhered to the sealing resin 5 by thermo-compression and, if necessary, thermal treatment using an oven or the like. Alternatively, the base 3B may be half-hard. In regard to the injection of resin into the space between the base 3A and base 3B, heat treatment by an oven or the like is carried out right after the resin injection. In the case of the thermo-compression, the distance between the dies, jigs, or rolls is arranged so that the multi-chip module has desired thickness. For the injection of resin between the base 3A and base 3B, desired thickness may be attained by using a spacer or a space is secured by fixing the bases onto dies, jigs, or the like. As discussed above, the base 3A and base 3B are provided on the respective surfaces of the multi-chip module and are disposed so as to sandwich and be equally distanced from the central plane horizontally cutting the multi-chip module.

In the multi-chip module of the present embodiment, to further reduce the warpage of the multi-chip module, the central planes horizontally cutting the bases 3A and 3B are preferably equally distanced from the central plane horizontally cutting the multi-chip module. If a shielding layer is required, the layer must be provided on the surface of the base 3A, which surface is opposite to the surface where the wirings 9 are formed, or must be formed on the surface where the wirings 9 are formed, avoiding the patterns of the wirings 9. In some cases, the shielding layer may be provided inside the base 3A.

In case where the shielding layers are provided on the base 3A and base 3B, the shielding layer is provided on the base 3B so that this shielding layer is substantially plane symmetrical with the shielding layer on the base 3A, with respect to the central plane horizontally cutting the multi-chip module 20. With this arrangement, the warpage of the multi-chip module 20 is restrained. The warpage of the multi-chip module is further restrained by arranging the central planes horizontally cutting the shielding layers on the bases 3A and 3B, respectively, to be plane symmetrical with respect to the central plane horizontally cutting the multi-chip module 20.

Subsequently, as shown in FIG. 2(e), external connection terminals 16 are formed. The terminals 16 can be suitably formed by any methods, such as a well-known method. For example, in the same manner as mounting the electronic components on the base 3A, solder bumps can be formed on the lands 11 by ball mounting, printing, or the like. Bumps may be made of another type of metal. The external connection terminals 16 may not be bumps. External connection may be achieved by leads, pins, ACF, ACP, or connectors. In the manner as above, the same numbers of electronic components are respectively provided on the upper and lower structures sandwiching the central plane of the multi-chip module, and the total area and volume of the bodies of the electronic components of the upper structure are substantially identical in the XY directions with the total area and volume of the bodies of the electronic components of the lower structure.

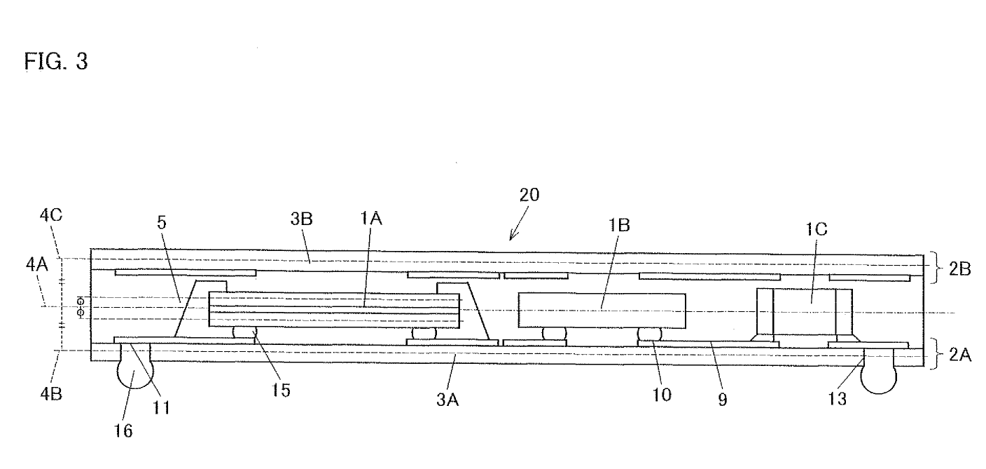

In the multi-chip module of FIG. 1, three electronic components are disposed on the same plane. Alternatively, as in the case of the multi-chip module shown in FIG. 3, plural electronic components may be partly disposed horizontally with respect to the multi-chip module (see electronic components 1A in FIG. 3). In FIG. 3, the same symbols (e.g. circles and double lines) indicate identical distances from the central plane horizontally cutting the multi-chip module.

As shown in FIG. 3, the electronic components 1A (each of which is 0.1 mm in thickness, for example) are two-tiered, and each of which is deposited by using a sheet-shaped die bond material (0.06 mm in thickness, for example) which is an insulating material.

The terminals 15 of the electronic component 1A are 0.05 mm in height, but are not limited to 0.05 mm. Also in this case, the body of the upper electronic component 1A is plane symmetrical with the body of the lower electronic component 1A with respect to the central plane horizontally cutting the multi-chip module 20. That is to say, the electronic components 1A are disposed in such a manner that the virtual surfaces equally distanced from and sandwiching the central plane horizontally cutting the multi-chip module 20 overlap the bodies of the upper and lower electronic components 1A, respectively. In the multi-chip module of the present embodiment, to further reduce the warpage of the multi-chip module 20, the central planes horizontally cutting the bodies of the upper and lower electronic components 1A are preferably equally distanced, from above and below, from the central plane horizontally cutting the multi-chip module 20.

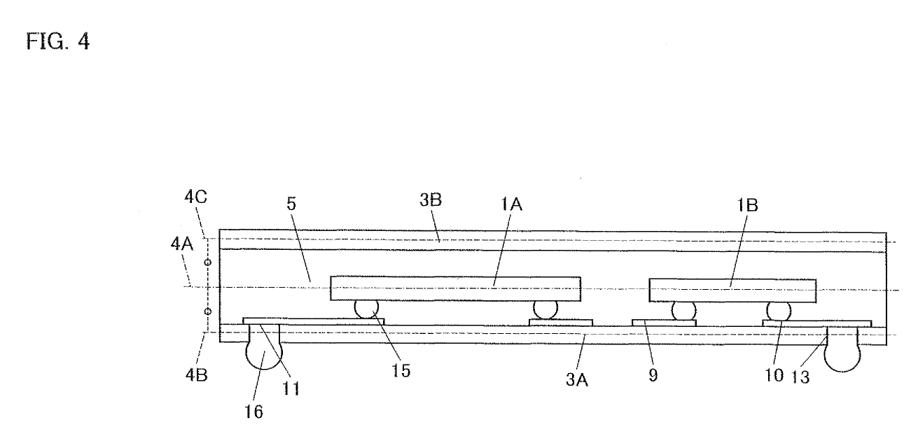

In the multi-chip modules 20 shown in FIGS. 1 and 3, the electronic component 1A, electronic component 1B, and electronic component 1C are different in thickness. Alternatively, as in the case of the multi-chip module 20 shown in FIG. 4, the electronic component 1A and the electronic component 1B may have the same thickness (e.g. 0.16 mm). If the electronic components having the same thickness are included in this manner, the multi-chip module is arranged as below. It is noted that segments indicated by the same symbols (e.g. circles) indicate the same distances from the central plane horizontally cutting the multi-chip module 20.

As shown in FIG. 4, the bodies of the electronic components 1A and 1B, which are main constituent materials, are disposed so as to overlap the central plane horizontally cutting the multi-chip module 20. Because the bodies of the electronic components 1A and 1B are disposed so as to overlap the central plane horizontally cutting the multi-chip module 20, the warpage of the multi-chip module 20 is reduced. In the multi-chip module of the present embodiment, to further reduce the warpage, for example, the base 3A and base 3B may be both 0.15 mm in thickness and the total thickness of the multi-chip module 20 may be 0.7 mm. the average height of the terminals 15 may be 0.1 mm both in the electronic component 1A and electronic component 1B. Note that these numerical values are mere examples and the present invention is not limited to them. The central plane horizontally cutting the multi-chip 20 is preferably arranged to overlap the central planes horizontally cutting the respective electronic components 1A and 1B, by suitably determining the height of the terminals 15. Although the wirings 9 are not formed on the base 3B in the example shown in FIG. 4, the warpage of the multi-chip module 20 can be reduced as above, by taking into account of the disposition of the electronic component 1A, electronic component 1B, base 3A and base 3B, in the horizontal cross sectional direction.

When the bases 3A and 3B are provided on the respective surfaces of the multi-chip 20 as in the cases of FIG. 1, FIG. 3, and FIG. 4 or when the bases 3A and 3B are disposed so as to sandwich the electronic component 1A, electronic component 1B, and electronic component 1C, preferably the base 3A and base 3B are additionally arranged as below. For example, a mesh or solid metal film is preferably provided at least on the area where the electronic components are provided, inside the bases 3A and 3B, the external surfaces (facing the outside of the multi-chip module), or the opposing surfaces (facing toward the inside of the multi-chip module). This makes it possible to block an influence of electromagnetic waves from the outside to inside the multi-chip module 20 or from the inside to outside of the multi-chip module 20.

The aforesaid mesh or solid pattern is preferably connected electrically with the ground terminals of the electronic components. Moreover, the mesh or solid pattern is preferably connected electrically with a particular external connection terminal of the multi-chip module 20. In consideration of influences on the warpage of the multi-chip module, the following arrangements are preferred. The shielding layers are preferably formed in both the upper structure and lower structure. Further preferably, the upper structure and lower structure have the same numbers of shielding layers. Preferably the bases on which the shielding layers are provided are preferably plane symmetrical with respect to the central plane horizontally cutting the multi-chip module. Further preferably, the shielding layers are disposed in a plane symmetrical manner with respect to the central plane horizontally cutting the multi-chip module. The warpage of the multi-chip module is further reduced by disposing the central planes horizontally cutting the respective shielding layers to overlap the central plane horizontally cutting the multi-chip module. Moreover, the warpage is further restrained by arranging the shielding layers on respective planes, which planes are plane-symmetrical with one another, to have the same area. It is preferable to keep the ratio of the larger total area to the smaller total area to be not higher than 120%. A local warpage of the multi-chip module is restrained if the shielding layers overlap one another when the multi-chip module is vertically viewed.

According to the arrangements above, electromagnetic waves and light are blocked in a more effective manner. In the meanwhile, the temperature of the multi-chip module 20 may increase on account of heat generation of the electronic components. Such increase in the temperature of the multi-chip module 20 can be restrained by providing a mesh or solid metal film. This is because heat dispersion is improved by a mesh or solid metal film having high heat conduction.

The mesh or solid metal film is preferably made of the same material as the wirings on the bases 3A and 3B, in consideration of manufacturing. The material may be optionally chosen, but is preferably copper. Copper excels in heat dispersion among metal materials. In this way, the heat increase in the multi-chip module 20 can be restrained. In case where the electronic components are fixed by a die bond material, heat conduction is improved when conductive particles are included in the die bond material. The die bond material may be optionally chosen, but metal bonding using solder which is a conductive material is preferable because improvement in heat conduction is expected. In case where the outermost surfaces of the wirings 9 on the base 3A and base 3B are made of gold (in this case, the outermost surface of the mesh and solid metal film may be made of gold, too), gold-silicon bonding is feasible if the electronic components have the bodies made of silicon. In this case, the base 3A and base 3B are preferably made of a material such as ceramic and silicon, which is not deteriorated by bonding with a high temperature.

### Embodiment 21

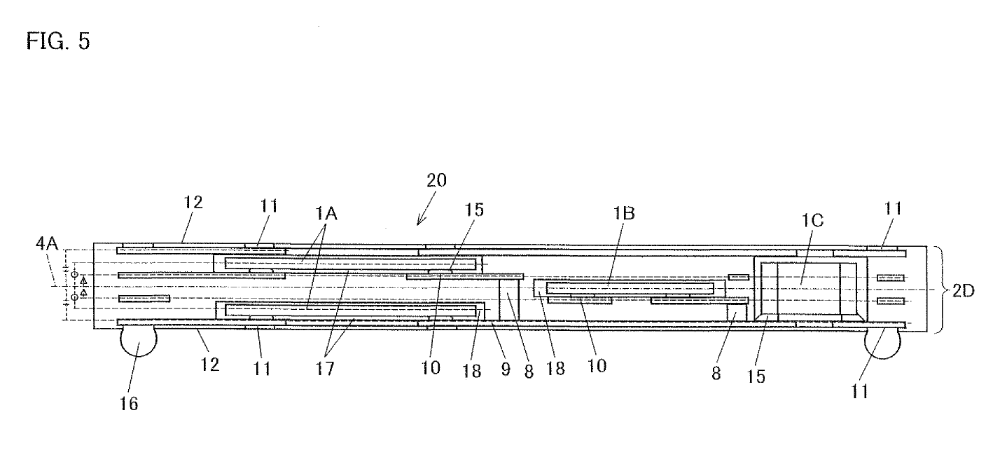

The following will explain a multi-chip module of the present embodiment with reference to FIG. 5.

FIG. 5 shows a horizontal cross section of the multi-chip module of the present embodiment. The multi-chip module of FIG. 5 is different from the multi-chip module of FIG. 1 in that there are three bases 3A, 3B, and 3C (all of them are 0.15 mm in thickness, for example) and four layers of wirings 9 (each of which is 0.02 mm in thickness, for example). Also, the wirings 9 are electrically connected to one another by wirings 8.

The number of layers of the bases and the number of layers of the wirings 9 are not particularly limited, and the number of layers can be arbitrarily determined. The warpage of the multi-chip module is reduced by arranging the bases 3A, 3B, 3C and so on and the bodies of the electronic components 1A, 1B, 1C, and so on are disposed in a substantially plane symmetrical manner with respect to the central plane of the multi-chip module 20.

In the multi-chip module of the present embodiment, the central planes horizontally cutting the respective bases 3A, 3B, and 3C are disposed in a plane symmetrical manner with respect to the central plane 4A horizontally cutting the multi-chip module 20. In other words, the central plane horizontally cutting the base 3C is disposed so as to overlap the central plane 4A horizontally cutting the multi-chip module 20 (which is 0.6 mm in thickness, for example), and the central planes horizontally cutting the base 3A and base 3B are disposed so as to be equally distanced from the central plane 4A horizontally cutting the multi-chip module 20. This further ensures the reduction of the warpage of the multi-chip module 20.

The following will describe the electronic components. In the multi-chip module of the present embodiment, there is an area where plural electronic components 1A (each of which is 0.07 mm in thickness, for example) are disposed in the direction orthogonal to the multi-chip module, and there is another area where electronic components are disposed along a single layer. The electronic component 1B (which is 0.07 mm in thickness, for example) and the electronic component 1C (which is 0.3 mm in thickness, for example) have the bodies overlapping the central plane 4A horizontally cutting the multi-chip module 20. The bodies of the two electronic components 1A are disposed so as to overlap the virtual surfaces which are equally distanced from the central plane of the multi-chip module 20. These arrangements reduce the warpage of the multi-chip module 20.

In the example shown in FIG. 5, to further ensure the reduction of the warpage, the central planes horizontally cutting the electronic component 1B and electronic component 1C are preferably disposed so as to overlap the central plane 4A of the multi-chip module 20, and the central planes horizontally cutting the two electronic components 1A, respectively, are preferably equally distanced from the central plane 4A horizontally cutting the multi-chip module 20.

The bodies of the electronic component 1B and electronic component 1C are different in thickness. Therefore, below the areas where the electronic component 1A, electronic component 1B, and electronic component 1C are mounted, the number of layers of the bases which are insulating materials and the number of layers of the wirings 9 (lands 10 and 11) which are conductive materials are differentiated so that the bodies of the electronic component 1B and electronic component 1C overlap the central plane horizontally cutting the multi-chip module. For example, while there is a single layer of base 3A in the area where the electronic component 1B is mounted, there is no base 3A in the area where the electronic component 1C is mounted. The wirings 9 (lands 10) are two-layered in the area where the electronic component 1B is mounted, whereas the wirings 9 are single-layered in the area where the electronic component 1C is mounted. In the area where the lower electronic component 1A is mounted, there is no layer of base and a single layer of wirings. On the other hand, in the area where the upper electronic component 1A is mounted, there are two layers of bases and three layers of wirings. In this manner, the number of layers of bases and the number of layers of wirings are differentiated so that the positions of the bodies of the electronic components are adjusted. As a matter of course, these specific numbers of layers of bases and wirings are mere examples, and the present invention is not limited to them.

In the multi-chip module of the present embodiment, an adhesive (which is, for example, 0.03-0.05 mm in thickness, and 0.02-0.03 mm in thickness after adhesion (thinner than this on the wirings), and the thickness of the adhesive can be suitably determined in consideration of the thickness of the wirings, the thickness of cavities 17 and 18, and spaces) is preferably adopted to adhere the bases 3A, 3B, and 3C with each other, in place of sealing resin. In case where the base 3A, base 3B and base 3C are adherent, an adhesive is unnecessary. For example, in case where the base 3A, base 3B, and base 3C are made of thermosetting resin, the base 3A, base 3B, and base 3C at this stage are half-hardened rather than completely hardened.

In the areas where the electronic components 1A, electronic component 1B, and electronic component 1C are mounted, there are cavities 17 and 18. The cavities 17 and cavities 18 are preferably filled with liquid resin, an adhesive for joining the bases, or the like. The liquid resin or adhesive is not particularly limited, and hence a well-known liquid resin or adhesive can be suitably used. On the bases 3A and 3B provided on the respective surfaces of the multi-chip module 20, the lands 11 of the wirings 9 are exposed. Members other than these lands 11 are covered with organic films 12. The organic films 12 are not particularly limited, and hence well-known organic films are suitably used. These organic films 12 function as solder resist. The thickness of the organic films 12 is not particularly limited, on condition that the members other than the lands 11 can be covered therewith. For example, the organic films 12 are about 0.03 mm in thickness. This arrangement makes it possible to expose the lands 11 but completely cover the other areas.

To the lands 11, other electronic components or the like can be attached. This allows the multi-chip module 20 to be used as a substrate on which electronic components are mounted. Alternatively, another multi-chip module 20 can be attached thereto. In this manner, when other components are further mounted, these components are easily mounted and connection failure after the mounting is reduced, because the multi-chip module 20 rarely warps.

Also, in the multi-chip module of the present embodiment, solder bumps are formed as external connection terminals 16, as in the case of Embodiment 1. By these external connection terminals 16, the multi-chip module of the present embodiment can be mounted on a substrate. In place of the bumps, bumps made of another type of conductive metal, leads, pins, ACF, ACP, and connectors may be used as the external connection terminals 16. The external connection terminals 16 are not limited to them.

The warpage after the multi-chip 20 is mounted on a substrate can be reduced by arranging the coefficients of linear expansion of the bases 3A, 3B, and 3C of the multi-chip module 20 to be substantially identical with the coefficient of linear expansion of the substrate on which the multi-chip module 20 is mounted. When the planar shape of the multi-chip module is long and narrow or irregular, the coefficients of linear expansion of the bases 3A, 3B, and 3C may be substantially the same only in the longitudinal direction or the maximal length direction of the multi-chip module. As a matter of course, the warpage of the multi-chip module can be further reduced if the coefficients of linear expansion are substantially the same in all of the XY directions. Similarly, as to the substrate on which the multi-chip module is mounted, when the planar shape of the multi-chip module is long and narrow or irregular, the coefficients of linear expansion of the bases 3A, 3B, and 3C may be substantially identical with the coefficient of linear expansion of the substrate, only in the longitudinal direction or the maximal length direction of the multi-chip module. As a matter of course, the warpage of the multi-chip module is further reduced if the coefficients of linear expansion of the bases 3A, 3B, and 3C are substantially identical with the coefficient of linear expansion of the substrate, in all of the XY directions.

The reduction of the warpage after the multi-chip module 20 is mounted on the substrate is further ensured if the elastic moduli and glass-transition temperatures of the bases 3A, 3B, and 3C of the multi-chip module 20 are substantially identical with those of the substrate on which the multi-chip module 20 is mounted. As to the elastic moduli, it is preferable to arrange the elastic moduli of the bases 3A, 3B, and 3C to be substantially the same in all of the XY directions of the multi-chip module. However, as in the case of the coefficients of linear expansion, depending on the planar shape of the multi-chip module, the warpage of the multi-chip module may be reduced by arranging the elastic moduli of the bases 3A, 3B, and 3C to be substantially the same only in the longitudinal direction or the maximal length direction of the multi-chip module. Similarly, as to the substrate on which the multi-chip module is mounted, the elastic moduli of the bases 3A, 3B, and 3C are preferably substantially the same as that of the substrate in the longitudinal direction or the maximal length direction of the multi-chip module, if the planar shape of the multi-chip module is long and narrow or irregular. As a matter of course, the warpage of the multi-chip module is further reduced if the elastic moduli of the bases 3A, 3B, and 3C are substantially identical with the elastic modulus of the substrate, in all of the XY directions.

For example, in the multi-chip module of the present embodiment, the bases 3A, 3B and 3C for the multi-chip module 20 and the substrate on which the multi-chip module 20 is mounted preferably adopt printed wiring substrates (glass-epoxy substrates) produced by impregnating liquid epoxy resin into glass cloth which is woven glass fiber. According to this arrangement, the warpage after the multi-chip module 20 is mounted on the substrate is reduced.

It is also preferable that the rate of content of glass cloth in the substrate on which the multi-chip module 20 is mounted be increased or the substrate include silica filler or the like. The multi-chip module 20 includes the electronic component 1A, electronic component 1B, and electronic component 1C. On this account, the overall coefficient of linear expansion tends to be low as compared to the case where only the base 3A, the substrate 3B, and the substrate 3C are provided. If the electronic components are silicon devices (or devices themselves are bodies), it is preferable to add glass cloth or silica filler to the substrate on which the multi-chip module 20 is mounted, at an amount corresponding to the volume or weight rate of the devices, because the coefficient of linear expansion of a silicon material is relatively similar to that of glass or silica.

In the multi-chip module of the present embodiment, the base 3C is also preferably produced by impregnating liquid epoxy resin into glass cloth which is woven glass fiber. The warpage of the multi-chip module 20 is reduced by either arranging the bases 3A and 3B which are symmetrical to have substantially the same coefficients of linear expansion, elastic moduli, and glass-transition temperatures and thickness, or by making the bases 3A and 3B of the same type of material. In case where the base 3C is made of a composite material, the warpage of the multi-chip module 20 is further reduced if the rates of content of the respective materials are substantially identical. Also, an internal stress is reduced by arranging the coefficient of linear expansion, elastic modulus, glass-transition temperature, or material of the base 3C overlapping the central plane to be substantially identical with those of the bases 3A and 3B. This arrangement prevents the bases from being detached from one another.

In case where the central plane horizontally cutting the base 3C overlaps the central plane horizontally cutting the multi-chip module 20, the warpage of the multi-chip module 20 is reduced even if the physical property or the type of material of the base 3C is different from that of the base 3A and base 3B. In the case above, the base 3C is disposed so as to overlap the central plane of the multi-chip module 20. If the central planes of the multi-chip module 20 and the base 3C do not overlap, the warpage of the multi-chip module is reduced but the magnitude of the effect is smaller than the above.

Even if the base 3A, base 3B, and base 3C are made of the same types of materials, the material component ratio, the sizes of included substances, and the distributions are still important if the bases are made of plural materials. For example, in case where the bases 3A-3C are produced by impregnating resin (epoxy resin, cyanate resin or the like) into glass fiber organic fiber, or the like, the coefficient of linear expansion, elastic modulus, and water absorption vary with the component ratio, the length of a fiber, the direction of fibers, the state of distribution (woven or non-woven), or the like. Therefore, in addition to the type of material, the base 3A, base 3B, and base 3C are preferably identical in the component ratio of the materials, the average length of fibers, the average diameter, and the state of distribution (woven or non-woven). In addition to fibers, filler may be included. Also in this case, the component ratio of the materials and the average size of the filler are preferably identical among the bases.

In the multi-chip module of the present embodiment, the base 3A and base 3B are preferably printed wiring substrate prepared by impregnating liquid epoxy resin into glass cloth which is woven glass fiber. In consideration of the above, the base 3A, base 3B, and base 3C are preferably arranged as follows. The difference in the component ratio of glass in resin among the bases 3A, 3B, and 3C is preferably not higher than 20 wt %. The difference in the glass-transition temperatures among the bases 3A, 3B, and 3C is preferably not higher than 20° C. The bases 3A, 3B, and 3C preferably have high glass-transition temperatures, and hence, for example, the glass-transition temperatures of 160-180° C. are preferable. The difference in the coefficients of linear expansion among the bases 3A, 3B, and 3C is preferably not higher than 10 ppm/° C. in at least one of the XY directions. When the temperatures are not lower than the glass-transition temperatures, the difference is preferably not higher than 100 ppm/° C. in at least one of the XY directions. The difference in water absorption among the bases 3A, 3B, and 3C is preferably not larger than 0.2 wt %.

In the multi-chip module of the present embodiment, the wirings 9 (lands 10 and 11) are disposed to be plane symmetrical with respect to the central plane horizontally cutting the multi-chip module 20. This arrangement further reduces the warpage of the multi-chip module 20. Furthermore, as shown in FIG. 5, in the multi-chip module of the present embodiment, the central planes horizontally cutting the wirings 9 (lands 10 and 11) of the respective layers are arranged to be symmetrical with respect to the central plane horizontally cutting the multi-chip module 20. This arrangement further reduces the warpage of the multi-chip module 20. (In the left side of FIG. 5, distances indicated by the same symbols are identical.) Preferably the area ratios of the wirings 9 of the respective layers are substantially the same. The difference between the area ratios of the respective groups of the writings 9 disposed in a symmetrical manner is preferably not higher than 20%.

The multi-chip module of the present embodiment may be arranged as follows. Upper and lower structures sandwiching the central plane horizontally cutting the multi-chip module 20 include a base 3A and a base 3C, and a base 3B and a base 3C, respectively. Each of the upper and lower structures includes the half of the body of the electronic component 1B, the half of the body of the electronic component 1C, and the body of an electronic component 1A. As such, the upper and lower structures include the same numbers of bodies, i.e., each of the structure includes 3 bodies. The total areas of the bodies of the electronic components in the upper and lower structures are preferably substantially identical in the XY directions, and the total volume of the bodies of the electronic components in the upper and lower structures are preferably substantially the same. Between the upper and lower structures, the ratio of the larger total volume to the smaller total volume or the ratio of the larger total area to the smaller total area is preferably not higher than about 120%. The bodies of the electronic components in the upper and lower structures are preferably disposed to overlap one another when viewed in the direction orthogonal to the multi-chip module. The upper and lower structures sandwiching the central plane in the cross sectional direction of the multi-chip module are preferably arranged to be substantially the same, and the upper and lower structures preferably have substantially the same coefficients of linear expansion in all of the XY directions. In case where the planar shape of the multi-chip module is long and narrow or irregular, the coefficient of linear expansion of the upper structure may be substantially identical with the coefficient of linear expansion of the lower structure, only in the longitudinal direction or the maximal length direction of the multi-chip module. As a matter of course, the warpage of the multi-chip module is reduced if the coefficient of linear expansion of the upper structure is substantially identical with the coefficient of linear expansion of the lower structure, in all of the XY directions. The substrate on which the multi-chip module 20 is mounted includes a larger amount of glass fiber, filler or the like than the upper and lower structures of the multi-chip module 20. This allows the substrate to have substantially the same coefficient of linear expansion as the upper and lower structures.

The substrate on which the multi-chip module 20 is mounted is not particularly limited, and hence a well-known substrate can be appropriately adopted. For example, the substrate may be made of a material totally different from the material of the bases of the multi-chip module 20. In this case, the coefficient of linear expansion of the substrate is preferably lower than the coefficient of linear expansion of each of the base 3A, base 3B, and base 3C. This reduces the warpage after the multi-chip module is mounted on the substrate. Also in the case of the substrate on which the multi-chip module is mounted, when the planar shape of the multi-chip module is long and narrow or irregular, the coefficient of linear expansion of the upper and lower structures may be substantially identical with the coefficient of linear expansion of the substrate, only in the longitudinal direction or the maximal length direction of the multi-chip module. As a matter of course, the warpage of the multi-chip module is further reduced if the coefficients of linear expansion of the upper and lower structures are substantially identical with the coefficient of linear expansion of the substrate, in all of the XY directions.

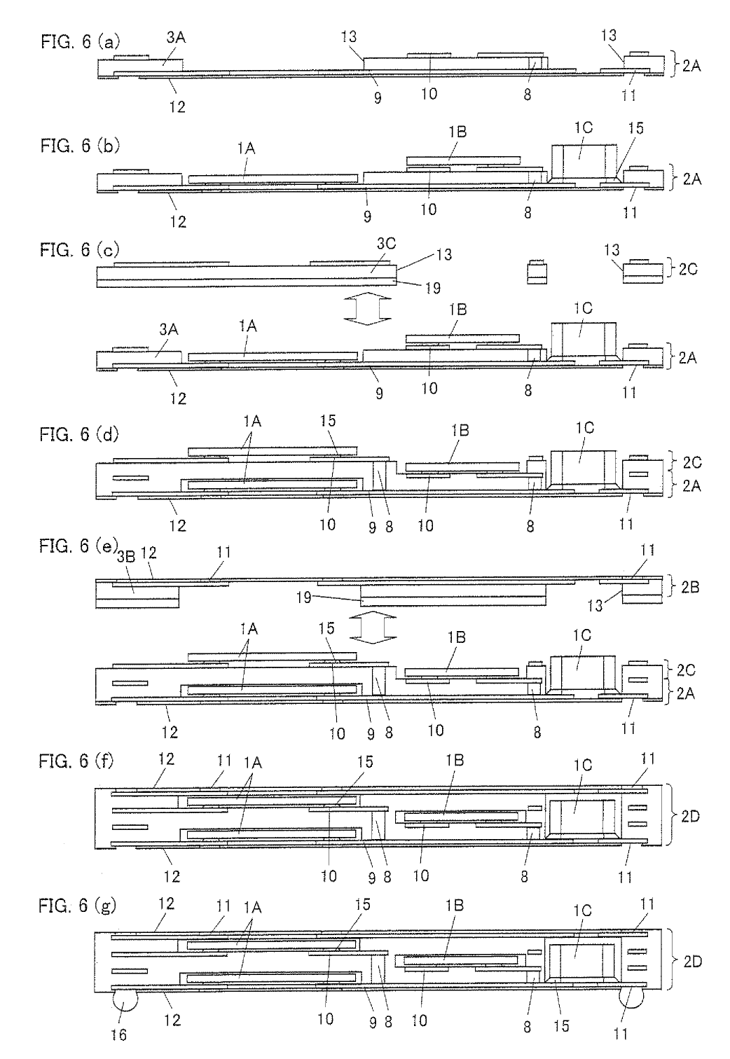

The following will explain a method of manufacturing a multi-chip module of the present embodiment, with reference to FIGS. 6(a)-6(g).

As shown in FIG. 6(a), a material produced by impregnating varnish thermosetting epoxy resin into glass cloth is prepared as a base 3A which is an insulating material, and wirings 9 (lands 10 and 11) are formed on the base 3A. Also, an organic film 12 is formed as solder resist, and openings are formed at the lands 11. The openings 13 may be formed by using a drill, for example. The base 3A preferably has substantially the same coefficient of linear expansion, elastic modulus, and glass-transition temperature as those of the substrate on which the multi-chip module 20 is mounted. Further preferably, the base 3A and the substrate are preferably made of the same material. Plural bases 3A are formed as connected strips or tapes of multi-chip modules, and separated into each base in the subsequent step (which is performed after the step shown in FIG. 6(g)) As to bases 3B and 3C, plural bases 3B and 3C are formed as connected strips or tapes of multi-chip modules, too. For the sake of convenience, the figure illustrates a cross section of a single multi-chip module.

If a shielding layer is required and the shielding layer is provided on one of the surfaces of the base 3A, the layer is preferably formed on the surface where the wirings 9 are formed, avoiding the patterns of the wirings 9, or the shielding layer and the wirings 9 are preferably insulated by the organic film 12. The wiring 9 for grounding is preferably connected electrically with the shielding layer. In case where the shielding layer is provided on the surface, of the base 3A, which faces inward, the organic film 12 may be provided on this surface so as to insulate the wirings 9 from the shielding layer. In this case, however, it is required to form, at areas of the organic film 12 corresponding to the terminals of the electronic components, openings for electric connection with the wirings 9, and required to surely insulate the terminals other than the grounding terminals of the electronic components from the shielding layer, by the organic film 12. Alternatively, two or more organic films 12 may be formed on at least one of the surfaces of the base 3A. This makes it possible to insulate the wirings 9 from the shielding layer, insulate neighboring terminals or the like of the electronic components from one another, insulate the outside of the multi-chip module from the inside, or protect the inside of the multi-chip module. The shielding layer may be provided inside of the base 3A (inside in the horizontal cross sectional direction of the base 3A).

Subsequently, as shown in FIG. 6(b), on the wirings 9 (lands 10), electronic components 1A, electronic component 1B, and electronic component 1C are mounted in the same plane. In doing so, the heights of the electronic components 1A, electronic component 1B, and electronic component 1C are different on the base 3A. Below the electronic component 1A (lower layer) and the electronic component 1C, there are no base and a single layer of wiring. On the other hand, below the electronic component 1B, there are a single layer of base and two layers of wirings.

According to the method of manufacturing the multi-chip module of the present embodiment, the heights of the electronic component 1A, electronic component 1B, and electronic component 1C can be adjusted by a method other than the aforesaid method by which the numbers of layers of bases and wirings are suitably changed. For example, the heights of the electronic component 1A, electronic component 1B, and electronic component 1C can be adjusted by suitably differentiating the heights of the terminals 15 of the electronic component 1A, electronic component 1B, and electronic component 1C. In doing so, for example, the heights of the terminals 15 can be varied by increasing an amount of paste solder supplied to the land 11 on which the electronic component 1C is mounted, as compared to amounts of solder supplied to the lands on which the electronic component 1A and electronic component 1B are mounted.

After feeding solder to the lands, the electronic component 1A, electronic component 1B, and electronic component 1C are mounted by using a mounter, and electric connection is then established by heat treatment. In this manner, the electronic components 1B and 1C are disposed so that the bodies of the electronic components 1B and 1C overlap the central plane horizontally cutting the multi-chip module. According to the method of manufacturing the multi-chip module of the present embodiment, to further ensure the reduction of the warpage of the multi-chip module, the number of layers of bases, the number of layers of wirings, and the heights of the terminals 15 are preferably adjusted so that the central planes horizontally cutting the respective bodies of the electronic component 1B and electronic component 1C overlap the central plane horizontally cutting the multi-chip module. Although the heights of the terminals 15 are not particularly limited, the height of the terminals 15 of the electronic component 1A and electronic component 1B are preferably arranged to be 0.04 mm and the height of the terminals 15 of the electronic component 1C is preferably arranged to be 0.1 mm, for example.

According to the method of manufacturing the multi-chip module of the present embodiment, the terminals 15 are made of a solder material. Not limited to this, the terminals 15 may be bumps made of a conductive material such as copper and gold. In case where bumps having desired heights are formed by electroplating, the heights are preferably adjusted by varying the process time or current density.

The bumps may be formed by thin metallic wires. In this case, the bumps are preferably formed in manner of the first bonding of wire bonding. The heights of the bumps can be suitably adjusted by varying, for example, the wire diameter and the pressure for the bonding.

The electronic components 1A and 1B may be mounted in a face-up manner. In this case, the die bond material is preferably arranged to have desired thickness. Also, electric connections between the electronic component 1A and electronic component 1B are preferably achieved by wire bonding.

Thereafter, each space between the neighboring terminals 15 of the electronic component 1A, electronic component 1B, and electronic component 1C is filled with liquid resin (e.g. underfill material; not illustrated). In case where the electronic component 1A and electronic component 1B are mounted in a face-up manner and the electronic components 1A and 1B are connected to the base A by bonding wires, preferably liquid resin is dropped in order to protect the bonding wires. If necessary, liquid resin is preferably dropped so as to cover the electronic component 1A, electronic component 1B, and electronic component 1C. If a cavity 18 will be filled with the same liquid resin later, the liquid resin may be left half-hard at this stage, without completely hardening the same. In case where the cavity 18 is not filled with liquid resin or the cavity is filled with another type of resin, the liquid resin is preferably hardened completely at this stage, in consideration of handling.

In the present embodiment, the liquid resin filing the space between the terminals of the cavity 17 is preferably injected into the cavity 17, after the deposition of the base 3A, base 3B, and base 3C. As a result of this the electronic component 1A, electronic component 1B, and electronic component 1C are protected from physical and chemical damages from the outside. Furthermore, since the resin filing the space (cavity 17) between the terminals is identical with the resin filing the cavity 18, the management of resin in the manufacturing process is easy. In case where plural types of resins are used in the above, a boundary surface between resins having different physical properties is formed in the multi-chip module. Since peeling tends to occur at a boundary surface between resins having different physical properties, peeling at the boundary surface occurs in response to a slight physical or chemical damage. Such peeling at the boundary surface is restrained if the same resin is used. To fill the cavity by resin, a path (not illustrated) for guiding liquid resin to the cavity and a path (not illustrated) for releasing air from the cavity are preferably provided. These paths reduce voids in the resin in the cavity.

Subsequently, as shown in FIG. 6(c), the base 3C which has substantially the same coefficient of linear expansion as that of the base 3A is preferably prepared. In case where the planar shape of the multi-chip module is long and narrow or irregulars the warpage of the multi-chip module is reduced by arranging the coefficient of linear expansion of the base 3C to be substantially identical with the coefficient of linear expansion of the base 3A only in the longitudinal direction or the maximal length direction of the multi-chip module. In the present embodiment, to further reduce the warpage of the multi-chip modules the bases 3C and 3A having substantially the same coefficients of linear expansion in all of the XY directions are preferable. Further preferably, the base 3C has substantially the same elastic modulus and glass-transition temperature as those of the base 3A, and further preferably the base 3C is made of the same type of material as the base 3A. In the base 3C, wirings 9 (lands 10), openings 13 at the areas of an electronic component 1B and electronic component 1C, and an adhesive 19 are formed. As to the elastic modulus, in case where the planar shape of the multi-chip module is long and narrow or irregular, the warpage of the multi-chip module is reduced by arranging the elastic modulus of the base 3C to be substantially identical with the elastic modulus of the base 3A only in the longitudinal direction or the maximal length direction of the multi-chip module. In the present embodiment, to further reduce the warpage of the multi-chip module, the bases 3C and 3A having substantially the same elastic moduli in all of the XY directions are preferable.

If a shielding layer is necessary and the shielding layer is provided on the wiring-formed surface of the base 3C, preferably the shielding layer is formed so as to avoid the pattern of the wirings 9 or the shielding layer is provided in such a manner that the wirings 9 are insulated from the shielding layer by the organic film 12. In this case, it is required to form, at the areas of the organic film 12 corresponding to the terminals of the electronic components, openings for electric connection with the wirings 9, and required to surely insulate the terminals other than the grounding terminals of the electronic components from the shielding layer. In doing so, the wirings 9 for grounding are preferably electrically connected to the shielding layer. The shielding layer is required to be insulated from the lands 11 (or external terminals 16) except the land 11 connected to the ground terminal. The land 11 connected to the grounding terminal or the external terminal 16 for grounding is preferably electrically connected to the shielding layer.

In case where the shielding layer is provided on the adhesive side of the base 3C, the shielding layer is preferably formed between the base 3C and the adhesive 19. To further ensure the contact between the adhesive 19 and the base 3C, an organic film 12 is preferably provided between the shielding layer and the adhesive 19. On at least one of the surfaces of the base 3C, two or more layers of organic films 12 may be provided. This makes it possible to insulate the wirings 9 from the shielding layer, insulate the shielding layer from the electronic components, insulate the neighboring terminals of the electronic components, and so on. The shielding layer may be provided inside the base 3A (inside in the horizontal cross sectional direction of the base 3A). In case where the shielding layer is provided on the base 3A in the lower structure of the multi-chip module 20, the base 3C on the central plane horizontally cutting the multi-chip module 20 is preferably provided so that the shielding layer in the base 3C exists inside the upper structure, in consideration of the reduction of the warpage of the multi-chip module 20. On the contrary, in case where the shielding layer is provided on the base 3B in the upper structure, which base is plane symmetrical with the base 3A, the base 3C on the central plane horizontally cutting the multi-chip module 20 is preferably provided so that the shielding layer on the base 3C exists inside the lower structure, in consideration of the reduction of the warpage of the multi-chip module 20. In case where the shielding layers are provided on both (i) the base 3B in the upper structure and (ii) the base 3A which is in the lower structure and is plane symmetrical with the base 3B, it is unnecessary to provided the shielding layer on the base 3C. However, if an electromagnetic or optical shielding is required inside the multi-chip module, the shielding layer is preferably provided in the base 3C. In this case, the shielding layer is provided inside the base 3C in such a manner that the shielding layer overlaps the central plane horizontally cutting the multi-chip module 20. With this arrangement, the warpage of the multi-chip module 20 is further reduced. In addition to this, the reduction of the warpage of the multi-chip module is further ensured if the central plane horizontally cutting the multi-chip module 20 overlaps the central plane horizontally cutting the shielding layer of the base 3C.

By the aforesaid adhesive 19, the substrate 3C is adhered to the substrate 3A. The surfaces of the electronic component 1A, electronic component 1B, and electronic component 1C may be covered with the adhesive 19, in place of the liquid resin. The adhesive 19 is not prerequisite. For example, if the base 3A, base 3C, or both of them is arranged to be half-hard, the bases 3A and 3C can be adhered to one another by thermocompression, without using the adhesive 19. The adhesion at this stage may be tentative. Permanent adhesion may be carried out after all of the base 3A, base 3B, and base 3C are deposited.

The base 3C is disposed so as to overlap the central plane horizontally cutting the multi-chip module. The warpage of the multi-chip module is further reduced if the central plane horizontally cutting the multi-chip module is disposed so as to overlap the central plane horizontally cutting the base 3C.

Subsequently, as shown in FIG. 6(d), the electronic components 1A are mounted on the lands 10 of the base 3C. Subsequently, between the terminals 15 (in the cavity 17) of each electronic component 1A, liquid resin such as an underfill material is injected. In doing so, as in the case of FIG. 6(b), the liquid resin may be half-hard rather than completely hardened. If necessary, liquid resin may be dropped to cover the electronic components 1A. Furthermore, as discussed above, liquid resin is preferably injected after the deposition of the base 3A, base 3B, and base 3C. The central planes horizontally cutting the bodies of the upper and lower electronic components 1A are preferably arranged in a plane symmetrical manner with respect to the central plane horizontally cutting the multi-chip module.

Subsequently, as shown in FIGS. 6(e) and 6(f), the base 3B is attached. Being similar to the base 3C, the base 3B preferably has the same coefficient of linear expansion as the base 3A. In case where the planar shape of the multi-chip module is long and narrow or irregular, the warpage of the multi-chip module is reduced by arranging the coefficient of linear expansion of the base 3B to be substantially identical with the coefficient of linear expansion of the base 3A only in the longitudinal direction or the maximal length direction of the multi-chip module. In the present embodiment, to further reduce the warpage of the multi-chip module, the bases 3B and 3A having substantially the same coefficients of linear expansion in all of the XY directions are preferable.

The base 3B preferably has substantially the same elastic modulus and glass-transition temperature as those of the base 3A, and most preferably the bases 3B and 3A are made of the same type of material. In the base 3B, the wirings 9 (lands 11), openings 13 at the areas of the electronic component 1A and the electronic component 1C, an adhesive 19, and an organic film 12 as solder resist are formed. As to the elastic modulus, in case where the planar shape of the multi-chip module is long and narrow or irregular, the warpage of the multi-chip module is reduced by arranging the elastic modulus of the base 3B to be substantially identical with the elastic modulus of the base 3A only in the longitudinal direction or the maximal length direction of the multi-chip module. In the present embodiment, to further reduce the warpage of the multi-chip module, the bases 3B and 3A having substantially the same elastic moduli in all of the XY directions are preferable.

If a shielding layer is necessary, preferably the shielding layer is formed so as to avoid the pattern of the wirings 9 or the shielding layer is provided in such a manner that the wirings 9 are insulated from the shielding layer by the organic film 12. The wiring 9 for grounding is preferably connected electrically with the shielding layer. Also, two or more organic films 12 may be formed on at least one of the surfaces of the base 3A. This makes it possible to insulate the wirings 9 from the shielding layer, insulate the electronic components from the shielding layer, insulate the neighboring terminals of the electronic components from each other, insulate the outside of the multi-chip module from the inside, or protect the inside of the multi-chip module. The shielding layer may be provided inside of the base 3B (inside in the horizontal cross sectional direction of the base 3B). It is noted that the warpage of the multi-chip module is further restrained if the number of shielding layers on the base 3B is identical with the number of shielding layers on the base 3A. The reduction of the warpage of the multi-chip module is further ensured if the shielding layer of the base 3B is disposed so as to be plane symmetrical with the shielding layer of the base 3A.

The adhesive 19 may cover the surfaces of the electronic component 1A, electronic component 1B, and electronic component 1C, in place of the liquid resin. The adhesive 19 is not always required. If either (i) the base 3B or 3C (and the base 3A) or (ii) the base 3B and 3C (and the base 3A) is (are) arranged to be half-hard, it is possible to adhere the base 3B to the base 3C by thermo-compression. In the case of the thermo-compression, the distance between the dies, jigs, or rolls is arranged so that the multi-chip module has desired thickness. In doing so, the base 3A and base 3B are preferably disposed in a substantially plane symmetrical manner, with respect to the central plane horizontally cutting the multi-chip module. Each of these base 3A and base 3B is disposed at the upper or lower surface of the multi-chip module. The warpage of the multi-chip module is further reduced if the central planes horizontally cutting the respective bases 3A and 3B are arranged to be plane symmetrical with respect to the central plane horizontally cutting the multi-chip module.

Subsequently, as shown in FIG. 6(g), external connection terminals 16 are formed. The external connection terminals 16 can be made by any methods, and hence the terminals 16 can be suitably formed by a well-known method. For example, as in the case of Embodiment 1, solder bumps may be formed on the lands 11 by ball mounting or printing.

The external connection terminals 16 may not be bumps. External connection may be achieved by leads, pins, ACF, ACP, or connectors. After the steps above, strip-shaped or tape-shaped bases are separated into each multi-chip module, and the multi-chip module is completed. In this multi-chip module, the bodies of the electronic components 1A, electronic component 1B, and electronic component 1C are disposed in a symmetrical manner with respect to the central plane horizontally cutting the multi-chip module. As a result, each of the upper and lower structures sandwiching the central plane horizontally cutting the multi-chip module includes the half of the body of the electronic component 1B, the half of the body of electronic component 1C, and the entire body of the electronic component 1A. Between the upper and lower structures, the total area and volume of the bodies of the electronic component 1A, electronic component 1B, and electronic component 1C are substantially identical with one another in the planar direction.

As in the multi-chip module of the present embodiment, when the base 3A and base 3B are provided at the respective surfaces of the multi-chip module or the bases 3A, 3B, and 3C are disposed so as to sandwich the electronic component 1A, electronic component 1B, and electronic component 1C, the base 3A and base 3B (and the base 3C) preferably further include the following arrangements.

For example, at areas where the electronic components are mounted inside, on the top surfaces, or the bottom surfaces of the base 3A and base 3B, mesh or solid metal films are preferably provided. This makes it possible to block the influences of electromagnetic waves from the outside to the inside of the multi-chip module, electromagnetic waves from the inside to the outside, electromagnetic waves between the internal electronic components, light from the outside to the inside, light between the internal electronic components (in case where the electronic components are light emitting elements). The mesh or solid patterns are preferably connected to a particular external connection terminal of the multi-chip module. A temperature of the multi-chip module may increase on account of heat generated from the electronic components. Such temperature increase can be restrained by the mesh or solid metal films.

The mesh or solid metal film is preferably made of the same material as the wirings on the bases 3A, 3B, and 3C, in consideration of manufacturing. The material is not particularly limited, but is preferably copper. To reduce the warpage of the multi-chip module, the following arrangements are preferred. The shielding layers are preferably formed on both the upper structure and the lower structure. More preferably the total number of shielding layers in the upper structure is identical with the total number of shielding layers in the lower structure. The bases on which the shielding layers are provided are preferably disposed in a plane symmetrical manner with respect to the central plane horizontally cutting the multi-chip module. Further preferably, the shielding layers are disposed in a plane symmetrical manner with respect to the central plane horizontally cutting the multi-chip module, and the warpage of the multi-chip module is further reduced if the central planes horizontally cutting the respective shielding layers are disposed so as to overlap the central plane horizontally cutting the multi-chip module. Moreover, the warpage is further restrained by arranging the shielding layers on respective planes, which planes are plane-symmetrical with one another, to have the same area. It is preferable to keep the ratio of the larger total area to the smaller total area to be not higher than 120%. A local warpage of the multi-chip module is restrained if the shielding layers overlap one another when the multi-chip module is vertically viewed.

In case where the electronic components are fixed by a die bond material, heat conduction is improved when conductive particles are included in the die bond material. The die bond material is not particularly limited, but metal bonding using solder which is a conductive material is preferable because improvement in heat conduction is expected. In case where the outermost surfaces of the wirings 9 on the base 3A, 3B, and 3C are made of gold (in this case, the outermost surface of the mesh and solid metal film may be made of gold, too), gold-silicon bonding is feasible if the electronic components have bodies made of silicon. In this case, the base 3A, 3B, and 3C are preferably made of a material such as ceramic and silicon, which is not deteriorated by bonding with a high temperature.

In the present invention, the multi-chip module, a manufacturing method thereof, a mounting structure of the multi-chip module, and a manufacturing method of the structure may be arranged as follows.

The multi-chip module of the present invention is preferably arranged so that the constituent materials are arranged such that central planes which horizontally cut the respective constituent materials are plane symmetrical with respect to the central plane which horizontally cuts the multi-chip module.

According to this arrangement, an even number of constituent materials can be disposed so as to overlap one another in the direction vertical to the multi-chip module. Furthermore, since the central planes horizontally cutting these even number of constituent materials are disposed in a plane symmetrical manner with respect to the central plane which horizontally cuts the multi-chip module, the warpage of the multi-chip module is further reduced.

The multi-chip module of the present invention is preferably arranged such that a central plane which horizontally cuts at least one of the constituent material overlaps the central plane which horizontally cuts the multi-chip module.

According to this arrangement, an odd number of constituent materials can be disposed so as to overlap one another in the direction vertical to the multi-chip module. Furthermore, since the central planes horizontally cutting these odd number of constituent materials are disposed in a plane symmetrical manner with respect to the central plane which horizontally cuts the multi-chip module, the warpage of the multi-chip module is further reduced.

The multi-chip module of the present invention is preferably arranged such that each of the constituent materials is a material selected from the group consisting of electronic component, base, and wiring.

According to this arrangement, main constituent materials of the multi-chip module are electronic components, bases, wirings, and the like. Therefore, if these main constituent materials are disposed in a substantially plane symmetrical manner with respect to the central plane which horizontally cuts the multi-chip module, most of the arrangements in the upper and lower structures in the multi-chip module are arranged in a plane symmetrical manner with respect to the central plane which horizontally cuts the multi-chip module. As a result, the warpage of the multi-chip module is further reduced. As a result, the warpage of the multi-chip module is further reduced.

The multi-chip module of the present invention is preferably arranged such that the bases which are disposed in a plane symmetrical manner have substantially identical coefficients of linear expansion at least in a maximal length direction of the multi-chip module in plane.

According to this arrangement, the bases have substantially the same coefficients of linear expansion at least in the maximal length direction of the multi-chip module in plane. Therefore, the bases in the upper and lower structures of the multi-chip module warp in opposite directions in the same degree, in response to a temperature change. Therefore the warpage of the multi-chip module is further reduced.

The multi-chip module of the present invention is preferably arranged such that the bases which are disposed in a plane symmetrical manner have substantially identical elastic moduli and glass-transition temperatures.

The multi-chip module of the present invention is preferably arranged such that the bases which are disposed in a plane symmetrical manner are made of the same material.

According to the arrangements above, not only the disposition of the bases but also the physical properties of the bases are arranged in a substantially plane symmetrical manner with respect to the central plane which horizontally cuts the multi-chip module. It is therefore possible to further reduce the warpage of the multi-chip module.

The multi-chip module of the present invention is preferably arranged such that the bases which are disposed in a plane symmetrical manner are made of resin including fibers or particles made of an organic material or an inorganic material, and rates of content of the fibers or the particles are substantially identical between the bases which are disposed in a plane symmetrical manner.

According to the arrangement above, since the bases are made of resin including fibers or particles made of an organic or inorganic material, the physical properties (e.g. coefficient of linear expansion, elastic modulus) of the resin can be approximated to desired values. For example, the physical properties of the bases can be brought close to those of the electronic components. Even if the bases are made of the same type of material, the physical properties of them are slightly different if the rate of content are different therebetween. Therefore, the warpage of the multi-chip module is further reduced by arranging the rates of content to be substantially the same.

The multi-chip module of the present invention is preferably arranged such that on or in the bases, shielding layers are provided, respectively.

This arrangement makes it possible to protect the inside of the multi-chip module.

The multi-chip module of the present invention is preferably arranged such that the shielding layers are disposed in a plane symmetrical manner with respect to the central plane which horizontally cuts the multi-chip module.

According to the arrangement above, many of the arrangements in the multi-chip module are disposed in a plane symmetrical manner with respect to the central plane which horizontally cuts the multi-chip module. As a result, the warpage of the multi-chip module is further reduced.

The multi-chip module of the present invention is preferably arranged such that the wirings which are disposed in a plane symmetrical manner have substantially identical areas.

According to this arrangement, the opposite warping forces of the upper and lower structures further equal out. As a result, the multi-chip module can reduce the warpage thereof.

Moreover, according to the arrangement above, in each of the planes which are plane symmetrical with respect to the central plane which horizontally cuts the multi-chip module, the wirings are arranged to be substantially plane symmetrical. As a result, a local warpage of the multi-chip module can be reduced.

The multi-chip module of the present invention is preferably arranged such that each of the electronic components is connected to the base by at least one of an insulating material and a conductive material.

According to this arrangement, at least one of the insulating material or the conductive material is adjusted in each electronic component. It is therefore easy to dispose the electronic components in a substantially plane symmetrical manner with respect to the central plane which horizontally cuts the multi-chip module. As a result, the warpage of the multi-chip module is easily reduced.

The multi-chip module of the present invention is preferably arranged such that positions of the electronic components in the multi-chip module are determined by adjusting the number of layers of the bases, the wirings, or both of the bases and the wirings.

According to this arrangement, since the positions of the electronic components in the multi-chip module are determined by adjusting the numbers of layers of the bases and wirings, no other measurements are required to determine the positions of the electronic components, but the effect is enhanced if another measurement is concurrently used. As a result, the arrangements of the upper and lower structures of the multi-chip module are further plane symmetrical with respect to the central plane which horizontally cuts the multi-chip module. As a result, the warpage of the multi-chip module is reduced.

A mounting structure of a multi-chip module of the present invention, in which one of the multi-chip module of the present invention is mounted on a substrate, is characterized in that the coefficients of linear expansion are substantially identical between the bases and the substrate.

According to this arrangement, the mounting of the multi-chip module on the substrate is further facilitated and connection failure in the use environment after the mounting is further restrained.

The mounting structure of the present invention is preferably arranged such that the bases and the substrate are made of the same material.

According to this arrangement, the mounting of the multi-chip module on the substrate is further facilitated and connection failure in the use environment after the mounting is further restrained.

The multi-chip module of the present invention is preferably arranged such that the number of the electronic components in the upper structure is identical with the number of the electronic components in the lower structure.

The multi-chip module of the present invention is preferably arranged such that the total area of the electronic components in the upper structure is substantially identical with the total area of the electronic components in the lower structure.

The multi-chip module of the present invention is preferably arranged such that the total volume of the electronic components in the upper structure is substantially identical with the total volume of the electronic components in the lower structure.

According to the arrangements above, the degrees of in-plane elongation and contraction of the upper and lower structures of the multi-chip module are further brought close to one another. As a result, the warpage of the multi-chip module is reduced.

The multi-chip module of the present invention is preferably arranged such that the electronic components of the upper structure overlap the electronic components of the lower structure, when the multi-chip module is viewed in a vertical direction.

According to this arrangement, since the electronic components are arranged to overlap one another when viewed in the direction vertical to the multi-chip module, the degrees of local in-plane elongation and contraction of the upper and lower structures are substantially the same. In other words, because an in-plane internal stress locally occulting in the upper and lower structures is restrained, deformation due to an internal stress is restrained. As a result, local deformation of the multi-chip module is reduced.

The multi-chip module of the present invention is preferably arranged such that a coefficient of linear expansion of the upper structure is substantially identical with a coefficient of linear expansion of the lower structure, at least in a maximal length direction of the multi-chip module in plane.

According to this arrangement, the degrees of elongation and contraction of the upper and lower structures of the multi-chip module in the maximal length direction are further brought close to one another. In other words, the structures elongate or contract in the same direction and in the substantially same degrees, in response to a temperature change. As a result, the warpage of the multi-chip module is reduced. That is to say, if the degrees of elongation and contraction of the upper and lower structures are significantly different in the maximal length direction, the multi-chip module warps towards one of the upper and lower structures. When the degrees of elongation and contraction are similar, the forces affecting the upper and lower structures each other are reduced and hence the warpage of the multi-chip module is reduced. As a result, the warpage of the multi-chip module is reduced.

The multi-chip module of the present invention is preferably arranged such that the bases are disposed in a plane symmetrical manner with respect to the central plane which horizontally cuts the multi-chip module.

According to this arrangement, the warpage of the multi-chip module is further reduced.

The multi-chip module of the present invention is preferably arranged such that on or in the bases, shielding layers are provided, respectively.

This arrangement makes it possible to protect the inside of the multi-chip module.

The multi-chip module of the present invention is preferably arranged such that the shielding layers are included in the upper structure and the lower structure, respectively.

The multi-chip module of the present invention is preferably arranged such that the number of the shielding layers in the upper structure is identical with the number of the shielding layers in the lower structure.

According to the arrangements above, the arrangements in the upper structure become further similar to the arrangements in the lower structure. As a result, the warpage of the multi-chip module is further reduced.

The multi-chip module of the present invention is preferably arranged such that the shielding layers are disposed in a plane symmetrical manner, with respect to the central plane which horizontally cuts the multi-chip module.

This arrangement further reduces the warpage of the multi-chip module.

A mounting structure of a multi-chip module of the present invention, in which one of the multi-chip module of the present invention is mounted on a substrate, is characterized in that the upper structure, the lower structure, and the substrate have substantially the same coefficients of linear expansion at least in the maximal length direction of the multi-chip module in plane.

According to this arrangement, the upper structure, the lower structure, and the substrate have substantially the same coefficients of linear expansion at least in the maximal length direction of the multi-chip module in plane. Therefore the warpage of the multi-chip module and its mounting structure is further reduced.

A method of manufacturing a multi-chip module of the present invention including constituent materials therein, is characterized by including the step of disposing the constituent materials of the same type to be substantially plane symmetrical with respect to a central plane which horizontally cuts the multi-chip module.

According to the arrangement above, assuming that a part of the multi-chip module above the central plane which horizontally cuts the multi-chip module is an upper structure whereas the remaining part of the multi-chip module below the central plane is a lower structure, the arrangements in the upper structure and the arrangements in the lower structure are substantially plane symmetrical with respect to the central plane which horizontally cuts the multi-chip module. The upper and lower structures therefore warp in opposite directions. In other words, the upper and lower structures cancel out the warping forces of each other. Consequently the multi-chip module can reduce its warpage.

Furthermore, because the warpage of the multi-chip module is reduced, the multi-chip module can be surely connected to another substrate. Moreover, even if a temperature change occurs in the use environment after the mounting, connection failure between the substrate and the multi-chip module is restrained because the warpage of the multi-chip module is small.

The method of the present invention is preferably arranged such that the constituent materials are arranged such that central planes which horizontally cut the respective constituent materials are plane symmetrical with respect to the central plane which horizontally cuts the multi-chip module.

According to this arrangement, an even number of constituent materials can be disposed so as to overlap one another in the direction vertical to the multi-chip module. Furthermore, since the central planes horizontally cutting these even number of constituent materials are disposed in a plane symmetrical manner with respect to the central plane which horizontally cuts the multi-chip module, the warpage of the multi-chip module is further reduced.

The method of the present invention is preferably arranged such that a central plane which horizontally cuts at least one of the constituent material overlaps the central plane which horizontally cuts the multi-chip module.

According to this arrangement, an odd number of constituent materials can be disposed so as to overlap one another in the direction vertical to the multi-chip module. Furthermore, since the central planes horizontally cutting these odd number of constituent materials are disposed in a plane symmetrical manner with respect to the central plane which horizontally cuts the multi-chip module, the warpage of the multi-chip module is further reduced.

The method of the present invention is preferably arranged such that each of the constituent materials is a material selected from the group consisting of electronic component, base, and wiring.

According to this arrangement, main constituent materials of the multi-chip module are electronic components, bases, wirings, and the like. Therefore, if these main constituent materials are disposed in a substantially plane symmetrical manner with respect to the central plane which horizontally cuts the multi-chip module, most of the arrangements in the upper and lower structures in the multi-chip module are arranged in a plane symmetrical manner with respect to the central plane which horizontally cuts the multi-chip module. As a result, the warpage of the multi-chip module is further reduced. As a result, the warpage of the multi-chip module is further reduced.

The method of the present invention is preferably arranged such that each of the electronic components is connected to the base by at least one of an insulating material and a conductive material.

According to this arrangement, at least one of the insulating material or the conductive material is adjusted in each electronic component. It is therefore easy to dispose the electronic components in a substantially plane symmetrical manner with respect to the central plane which horizontally cuts the multi-chip module. As a result, the warpage of the multi-chip module is easily reduced.

The method of the present invention is preferably arranged such that the bases are formed at least on the top surface and the bottom surface of the multi-chip module.

According to this arrangement, the bases are disposed in a substantially plane symmetrical manner with respect to the central plane which horizontally cuts the multi-chip module. As a result, the warpage of the multi-chip module is reduced.

The method of the present invention is preferably arranged such that on or in the bases, shielding layers are provided, respectively.

This arrangement makes it possible to protect the inside of the multi-chip module.

The method of the present invention is preferably arranged such that the shielding layers are disposed in a plane symmetrical manner with respect to the central plane which horizontally cuts the multi-chip module.

According to the arrangement above, many of the arrangements in the multi-chip module are disposed in a plane symmetrical manner with respect to the central plane which horizontally cuts the multi-chip module. As a result, the warpage of the multi-chip module is further reduced.

A method of manufacturing a multi-chip module of the present invention including constituent materials therein, is characterized by including the step of forming, as the constituent materials, bases and electronic components in upper and lower structures sandwiching a central plane which horizontally cuts the multi-chip module

According to the arrangement above, principal parts of the upper structure above the central plane which horizontally cuts the multi-chip module and principal parts of the lower structure below the central plane are substantially identical. Therefore in terms of the elongation and contraction in one direction due to temperature changes, the upper and lower structures are identical with each other. In other words, since the difference in the degree of elongation and contraction between the upper and lower structures is small, an in-plane stress is restrained. As a result, the warpage of the multi-chip module is reduced.

Furthermore, because the warpage of the multi-chip module is reduced, the multi-chip module can be surely connected to another substrate. Moreover, even if a temperature change occurs in the use environment after the mounting, connection failure between the substrate and the multi-chip module is restrained because the warpage of the multi-chip module is small.

The method of the present invention is preferably arranged such that the number of the electronic components in the upper structure is identical with the number of the electronic components in the lower structure.

The method of the present invention is preferably arranged such that the total area of the electronic components in the horizontal direction in the upper structure is substantially identical with the total area of the electronic components in the horizontal direction in the lower structure.

The method of the present invention is preferably arranged such that the total volume of the electronic components in the upper structure is substantially identical with the total volume of the electronic components in the lower structure.

According to the arrangements above, the degrees of in-plane elongation and contraction of the upper and lower structures of the multi-chip module are further brought close to one another. As a result, the warpage of the multi-chip module is reduced.

The method of the present invention is preferably arranged such that the electronic components of the upper structure overlap the electronic components of the lower structure, viewing the multi-chip module in a vertical direction.

According to this arrangement, since the electronic components are arranged to overlap one another when viewed in the direction vertical to the multi-chip module, the degrees of local in-plane elongation and contraction of the upper and lower structures are substantially the same. In other words, because an in-plane internal stress locally occulting in the upper and lower structures is restrained, deformation due to an internal stress is restrained. As a result, local deformation of the multi-chip module is reduced.

The method of the present invention is preferably arranged such that a coefficient of linear expansion of the upper structure is substantially identical with a coefficient of linear expansion of the lower structure, at least in a maximal length direction of the multi-chip module in plane.

According to this arrangement, the degrees of elongation and contraction of the upper and lower structures of the multi-chip module in the maximal length direction are further brought close to one another. In other words, the structures elongate or contract in the same direction and in the substantially same degrees, in response to a temperature change. As a result, the warpage of the multi-chip module is reduced. That is to say, if the degrees of elongation and contraction of the upper and lower structures are significantly different in the maximal length direction, the multi-chip module warps towards one of the upper and lower structures. When the degrees of elongation and contraction are similar, the forces affecting the upper and lower structures each other are reduced and hence the warpage of the multi-chip module is reduced. As a result, the warpage of the multi-chip module is reduced.

The method of the present invention is preferably arranged such that the bases are disposed in a plane symmetrical manner with respect to the central plane which horizontally cuts the multi-chip module.

According to this arrangement, the warpage of the multi-chip module is further reduced.

The method of the present invention is preferably arranged such that on or in the bases, shielding layers are provided, respectively.

This arrangement makes it possible to protect the inside of the multi-chip module.

The method of the present invention is preferably arranged such that the shielding layers are included in the upper structure and the lower structure, respectively.

The method of the present invention is preferably arranged such that the number of the shielding layers in the upper structure is identical with the number of the shielding layers in the lower structure.

According to the arrangements above, the arrangements in the upper structure become further similar to the arrangements in the lower structure. As a result, the warpage of the multi-chip module is further reduced.

The method of the present invention is preferably arranged such that the shielding layers are disposed in a plane symmetrical manner, with respect to the central plane which horizontally cuts the multi-chip module.

This arrangement further reduces the warpage of the multi-chip module.

The method of the present invention is preferably arranged such that the bases provided in the upper and lower structures, respectively, are made of the same material.

According to this arrangement, the arrangements in the he upper and the arrangements in the lower structures of the multi-chip module are further brought close to one another. As a result, the warpage of the multi-chip module is reduced.

A method of manufacturing a multi-chip module of the present invention, including one of the methods of manufacturing the multi-chip module of the present invention, includes the step of mounting the multi-chip module on a substrate, the coefficients of linear expansion of the bases and the substrate being substantially identical at least in the maximal length direction of the multi-chip module in plane.

According to this arrangement, the mounting of the multi-chip module on the substrate is further facilitated and connection failure in the use environment after the mounting is further restrained.

The method of the present invention is preferably arranged such that the bases and the substrate are made of the same material.

According to this arrangement, the mounting of the multi-chip module on the substrate is further facilitated and connection failure in the use environment after the mounting is further restrained.

A method of manufacturing a multi-chip module of the present invention, including one of the methods of manufacturing the multi-chip module of the present invention, includes the step of mounting the multi-chip module on a substrate, the coefficients of linear expansion of the upper and lower structures and the substrate being substantially identical at least in the maximal length direction of the multi-chip module in plane.

According to this arrangement, the mounting of the multi-chip module on the substrate is further facilitated and connection failure in the use environment after the mounting is further restrained.

As discussed above, according to the multi-chip module, the method of manufacturing thereof, the mounting structure of the multi-chip module, and the method of manufacturing the structure of the present invention, constituent materials of the same type are substantially plane symmetrical with respect to the central plane which horizontally cuts the multi-chip module.

Furthermore, in the multi-chip module of the present invention, each of the upper and lower structures sandwiching the central plane which horizontally cuts the multi-chip module includes a base and electronic components, as the constituent materials.

It is therefore possible to reduce the warpage of the multi-chip module or the mounting structure of the multi-chip module, which is caused by a temperature change or the like.

Furthermore, as described above, the forces of warping the multi-chip are cancelled out by disposing the arrangements in the multi-chip module to be substantially plane symmetrical with respect to the central plane which horizontally cuts the multi-chip module.

In addition, as described above, the present invention is arranged in such a manner that each of the upper and lower structures sandwiching the central plane which horizontally cuts the multi-chip module includes a base and electronic components, as the constituent materials. Therefore in terms of the elongation and contraction in one direction due to temperature changes, the upper and lower structures are substantially identical with each other.

It is therefore possible to reduce the warpage of the multi-chip module or the mounting structure of the multi-chip module. In consideration of this, the present invention is useful in various types of multi-chip modules and multi-chip module mounting structures, and in a field of manufacturing components for them.

The present invention is not limited to the description of the embodiments above, but may be altered by a skilled person within the scope of the claims. An embodiment based on a proper combination of technical means disclosed in different embodiments is encompassed in the technical scope of the present invention.

What is claimed is:

1. A multi-chip module comprising constituent materials therein,
the constituent materials of the same type being disposed to be plane symmetrical with respect to a central plane which horizontally cuts the multi-chip module.

2. The multi-chip module as defined in claim 1,
wherein, the constituent materials are arranged such that central planes which horizontally cut the respective constituent materials are plane symmetrical with respect to the central plane which horizontally cuts the multi-chip module.

3. The multi-chip module as defined in claim 1,
wherein, a central plane which horizontally cuts at least one of the constituent material overlaps the central plane which horizontally cuts the multi-chip module.

4. The multi-chip module as defined in claim 1,
wherein, each of the constituent materials is a material selected from the group consisting of electronic component, base, and wiring.

5. The multi-chip module as defined in claim 4,
wherein, the bases which are disposed in a plane symmetrical manner have substantially identical coefficients of linear expansion at least in a maximal length direction of the multi-chip module in plane.

6. The multi-chip module as defined in claim 5,
wherein, the bases which are disposed in a plane symmetrical manner have substantially identical elastic moduli and glass-transition temperatures.

7. The multi-chip module as defined in claim 6,
wherein, the bases which are disposed in a plane symmetrical manner are made of the same material.

8. The multi-chip module as defined in claim 4,
wherein, the bases which are disposed in a plane symmetrical manner are made of resin including fibers or particles made of an organic material or an inorganic material, and
rates of content of the fibers or the particles are substantially identical between the bases which are disposed in a plane symmetrical manner.

9. The multi-chip module as defined in claim 4,
wherein, on or in the bases, shielding layers are provided, respectively.

10. The multi-chip module as defined in claim 9,
wherein, the shielding layers are disposed in a plane symmetrical manner with respect to the central plane which horizontally cuts the multi-chip module.

11. The multi-chip module as defined in claim 4,
wherein, the wirings which are disposed in a plane symmetrical manner have substantially identical areas.

12. The multi-chip module as defined in claim 4,
wherein, each of the electronic components is connected to the base by at least one of an insulating material and a conductive material.

13. The multi-chip module as defined in claim 4,
wherein, positions of the electronic components in the multi-chip module are determined by adjusting the number of layers of the bases, the number of layers of the wirings, or the numbers of layers of both the bases and the wirings.

14. A multi-chip module comprising constituent materials therein,
each of an upper structure and a lower structure sandwiching a central plane which horizontally cuts the multi-chip module including, as the constituent materials, a base and electronic components.

15. The multi-chip module as defined in claim 14,
wherein, the number of the electronic components in the upper structure is identical with the number of the electronic components in the lower structure.

16. The multi-chip module as defined in claim 14,
wherein, the total area of the electronic components in the horizontal direction in the upper structure is substantially identical with the total area of the electronic components in the horizontal direction in the lower structure.

17. The multi-chip module as defined in claim 14,
wherein, the total volume of the electronic components in the upper structure is substantially identical with the total volume of the electronic components in the lower structure.

18. The multi-chip module as defined in claim 16,
wherein, the electronic components of the upper structure overlap the electronic components of the lower structure, when the multi-chip module is viewed in a vertical direction.

19. The multi-chip module as defined in claim 14,
wherein, a coefficient of linear expansion of the upper structure is substantially identical with a coefficient of linear expansion of the lower structure, at least in a maximal length direction of the multi-chip module in plane.

20. The multi-chip module as defined in claim 16,
wherein, the bases are disposed in a plane symmetrical manner with respect to the central plane which horizontally cuts the multi-chip module.

21. The multi-chip module as defined in claim 16,
wherein, on or in the bases, shielding layers are provided, respectively.

22. The multi-chip module as defined in claim 21,
wherein, the shielding layers are included in the upper structure and the lower structure, respectively.

23. The multi-chip module as defined in claim 22,
wherein, the number of the shielding layers in the upper structure is identical with the number of the shielding layers in the lower structure.

24. The multi-chip module as defined in claim 22,
wherein, the shielding layers are disposed in a plane symmetrical manner, with respect to the central plane which horizontally cuts the multi-chip module.
